(19) United States
(12) Patent Application Publication
(10) Pub. No.: US 2026/0040668 A1
(43) Pub. Date: Feb. 5, 2026

(54) EPITAXIAL GROWTH OF FULLY-STRAINED AND DEFECT-FREE CFET SUPERLATTICES USING CARBON DOPING AND LAYERED MIDDLE DIELECTRIC ISOLATION

(71) Applicant: Applied Materials, Inc., Santa Clara, CA (US)

(72) Inventors: Himani ARORA, Albany, CA (US); Zichen ZHANG, Sunnyvale, CA (US); John TOLLE, Gilbert, AZ (US); He REN, San Jose, CA (US); Mark CONRAD, Cohoes, NY (US); Raman GAIRE, Mechanicville, NY (US)

(21) Appl. No.: 19/290,106

(22) Filed: Aug. 4, 2025

Related U.S. Application Data
(60) Provisional application No. 63/679,386, filed on Aug. 5, 2024.
(60) Provisional application No. 63/679,444, filed on Aug. 5, 2024.

(51) Int. Cl. H10D 84/83; H10D 84/01

(52) U.S. Cl. CPC H10D 84/832; H10D 84/0151

(57) ABSTRACT

Embodiments of the present disclosure relate to the field of electronic device manufacturing, and in particular, to multi-layered epitaxial stacks, such as complementary field-effect-transistors (cFETs). A method is used to fabricate a layered middle dielectric isolation (MDI) structure and carbon-doping of epitaxially grown silicon germanium layers together in the cFETs. In some embodiments, by integrating the layered MDI structure together with carbon-doping of SiGe layers into the cFETs, relaxation, wafer bow, and defects in a stack have been significantly reduced when compared to traditional stacks. Advantageously, multi-layered epitaxial stacks incorporate a greater number of silicon channels (e.g., pMOS and nMOS channels) when compared to traditional stacks. Furthermore, the selectivity in the downstream processes is improved by an order of magnitude. As such, trenches with high aspect ratio separate features, such that each feature includes the multi-layered epitaxial stack containing the MDI film disposed between the top and bottom FET modules.

### CROSS-REFERENCE TO RELATED APPLICATIONS

This application claims benefit to U.S. Prov. Appl. No. 63/679,386, filed on Aug. 5, 2024, and U.S. Prov. Appl. No. 63/679,444, filed on Aug. 5, 2024, which are both herein incorporated by reference in their entirety.

### BACKGROUND

### Field

Embodiments of the present disclosure relate to the field of electronic device manufacturing, and in particular, to transistors. More particularly, embodiments of the disclosure are directed to complementary field-effect transistors (cFETs), 3D NAND, and 3D DRAM structures, as well as the related fabrication processes.

### Description of the Related Art

The transistor is a key component of most integrated circuits. Since the drive current, and therefore speed, of a transistor is proportional to the gate width of the transistor, faster transistors generally require larger gate width. Thus, there is a tradeoff between transistor size and speed, and “fin” field-effect transistors (finFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. However, finFETs have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a FinFET structure, and a gate all around (GAA) structure. The GAA device structure includes several lattice matched channels suspended in a stacked configuration and connected by source/drain regions. The GAA structure provides good electrostatic control and can find broad adoption in complementary metal oxide semiconductor (CMOS) wafer manufacturing.

One example of gate-all-around (GAA) technology is complementary field effect transistor (cFET), where nFET and pFET nanowires/nanosheets are vertically stacked on top of each other. CFET transistors have increased on-chip device density and reduced area consumption when compared to GAA transistors. When stacking nFET and pFET in a monolithic manner, the n and p superlattice are deposited sequentially with a middle sacrificial layer that is selectively removed and replaced with a middle dielectric isolation during processing. The middle dielectric isolation layer serves to electrically isolate the lower-level GAA from the upper-level GAA.

Each n or p superlattice of a CFET includes alternating layers of channel layers and release layers. The release layers typically comprise silicon germanium (SiGe) with a low concentration of germanium (Ge). For etch contrast between the middle sacrificial layer verses the channel layers and the release layers, the middle sacrificial layer comprises SiGe with a high concentration of Ge. With such a high concentration of Ge in the middle sacrificial layer, however, the superlattice relaxes, and strain and mobility reduce, resulting in poor transistor performance due to reduced drive current.

High aspect ratio monolithic cFETs grown using heteroepitaxy often suffer from mechanical and thermal stresses, leading to layer relaxation, wafer bowing and channel defects. All of these are detrimental to a transistor's performance and make their integration into downstream processes difficult.

Accordingly, there is a need for semiconductor devices, cFET in particular, and methods of manufacturing such devices having a fully strained superlattice structure with channel layers that are free or substantially free of defects, and substrates that have a reduced wafer bow.

### BRIEF DESCRIPTION OF THE DRAWINGS

So that the manner in which the above recited features of the present disclosure may be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 depicts a complementary field-effect-transistor (cFET) stack, according to one or more embodiments described and discussed herein.

FIG. 2 depicts another cFET stack, according to one or more embodiments described and discussed herein.

FIG. 3 depicts another cFET stack, according to one or more embodiments described and discussed herein.

FIG. 4 depicts a plurality of features, such as cFETs, fabricated from the cFET stack illustrated in FIG. 2, according to one or more embodiments described and discussed herein.

FIG. 5 depicts a plurality of features, such as cFETs, fabricated from the cFET stack illustrated in FIG. 3, according to one or more embodiments described and discussed herein.

FIGS. 6A-6G depict a workpiece containing a cFET stack at different intervals while fabricating cFETs, according to one or more embodiments described and discussed herein.

To facilitate understanding, identical reference numerals have been used, where possible, to designate identical elements that are common to the Figures. It is contemplated that elements and features of one or more embodiments may be beneficially incorporated in other embodiments.

### SUMMARY

Embodiments of the present disclosure relate to the field of electronic device manufacturing, and in particular, to transistors. More particularly, embodiments of the disclosure are directed to multi-layered epitaxial stacks, such as complementary field-effect-transistors (cFETs), as well as the related fabrication processes. The method may be used to fabricate a layered middle dielectric isolation (MDI) structure and carbon-doping of epitaxially grown silicon germanium (SiGe) layers together in the cFETs. In some embodiments, by integrating a layered MDI structure together with carbon-doping of SiGe layers into the cFETs, relaxation, wafer bow, and defects in a stack have been significantly reduced when compared to traditional stacks. This leads to fully-strained stacks with “zero” defectivity as measured using XRDI within the scope of the tool. Advantageously, taller multi-layered epitaxial stacks incorporate a greater number of silicon channels (e.g., pMOS and nMOS channels) when compared to traditional stacks. Furthermore, the selectivity in the downstream processes is improved by an order of magnitude. As such, the trenches separating the features have high aspect ratios (e.g., greater than 10), such that each feature includes the multi-layered epitaxial stack containing the MDI film disposed between the top and bottom FET modules.

In one or more embodiments, a workpiece is provided and contains a multi-layered epitaxial stack disposed on a substrate, wherein the multi-layered epitaxial stack contains a middle dielectric isolation (MDI) film disposed between a bottom field effect transistor (FET) module and a top FET module, wherein the bottom FET module is disposed on the substrate and contains a plurality of first silicon germanium layers and silicon channel layers, wherein the first silicon germanium layers and the silicon channel layers are alternately stacked on each other, the top FET module is disposed on the MDI film, the top FET module contains a plurality of the first silicon germanium layers and the silicon channel layers, wherein the first silicon germanium layers and the silicon channel layers are alternately stacked on each other. The MDI film contains a plurality of the first silicon germanium layers and second silicon germanium layers, wherein the first silicon germanium layers the second silicon germanium layers are alternately stacked on each other, and wherein the second silicon germanium layers have a greater germanium concentration than the first silicon germanium layers. The MDI film also contains a bottom silicon epi layer disposed between the bottom FET module and the plurality of the first silicon germanium layers and the second silicon germanium layers and a top silicon epi layer disposed between the top FET module and the plurality of the first silicon germanium layers and the second silicon germanium layers.

In some embodiments, a workpiece is provided and contains a multi-layered epitaxial stack disposed on a substrate, wherein the multi-layered epitaxial stack contains an MDI film disposed between a FET module and a top FET module, wherein the bottom FET module is disposed on the substrate and contains a plurality of first silicon germanium layers and silicon channel layers, wherein three of the first silicon germanium layers are alternately stacked with two of the silicon channel layers, the top FET module is disposed on the MDI film, the top FET module contains a plurality of the first silicon germanium layers and the silicon channel layers, wherein two of the first silicon germanium layers are alternately stacked with two of the silicon channel layers, the MDI film contains a plurality of the first silicon germanium layers and second silicon germanium layers, wherein three of the second silicon germanium layers are alternately stacked with two of the first silicon germanium layers, and wherein the second silicon germanium layers have a greater germanium concentration than the first silicon germanium layers. The MDI film further contains a bottom silicon epi layer disposed between the bottom FET module and the plurality of the first silicon germanium layers and the second silicon germanium layers and a top silicon epi layer disposed between the top FET module and the plurality of the first silicon germanium layers and the second silicon germanium layers.

In other embodiments, a method of fabricating a film stack is provided and includes depositing a FET module on a substrate at a first temperature in a range from about 575° C. to about 625° C., depositing an MDI film on the bottom FET module at a second temperature in a range from about 575° C. to about 625° C., and depositing a top FET module on the MDI film at a third temperature in a range from about 575° C. to about 625° C. The bottom FET module contains a plurality of first silicon germanium layers and silicon channel layers, wherein the first silicon germanium layers and the silicon channel layers are alternately stacked on each other. The top FET module contains a plurality of the first silicon germanium layers and the silicon channel layers, wherein the first silicon germanium layers and the silicon channel layers are alternately stacked on each other. The MDI film contains a plurality of the first silicon germanium layers and second silicon germanium layers, wherein the first silicon germanium layers the second silicon germanium layers are alternately stacked on each other, and wherein the second silicon germanium layers have a greater germanium concentration than the first silicon germanium layers. The MDI film also contains a bottom silicon epi layer disposed between the bottom FET module and the plurality of the first silicon germanium layers and the second silicon germanium layers and a top silicon epi layer disposed between the top FET module and the plurality of the first silicon germanium layers and the second silicon germanium layers.

In one or more embodiments, a workpiece is provided and contains a plurality of features separated by trenches and disposed on a substrate, wherein each of the trenches has an aspect ratio of greater than 10, and wherein each of the features contains a multi-layered epitaxial stack containing an MDI film disposed between a FET module and a top FET module. The bottom FET module is disposed on the substrate and contains a plurality of first silicon germanium layers and silicon channel layers, wherein the first silicon germanium layers and the silicon channel layers are alternately stacked on each other, the top FET module is disposed on the MDI film, the top FET module contains a plurality of the first silicon germanium layers and the silicon channel layers, wherein the first silicon germanium layers and the silicon channel layers are alternately stacked on each other. The MDI film contains a plurality of the first silicon germanium layers and second silicon germanium layers, wherein the first silicon germanium layers the second silicon germanium layers are alternately stacked on each other, and wherein the second silicon germanium layers have a greater germanium concentration than the first silicon germanium layers. The MDI film also contains a bottom silicon epi layer disposed between the bottom FET module and the plurality of the first silicon germanium layers and the second silicon germanium layers and a top silicon epi layer disposed between the top FET module and the plurality of the first silicon germanium layers and the second silicon germanium layers.

In some embodiments, a workpiece is provided and contains a plurality of features separated by trenches and disposed on a substrate, wherein each of the trenches has an aspect ratio of greater than 10, and wherein each of the features contains a multi-layered epitaxial stack containing an MDI film disposed between a FET module and a top FET module. The bottom FET module is disposed on the substrate and contains a plurality of first silicon germanium layers and silicon channel layers, wherein four of the first silicon germanium layers are alternately stacked with three of the silicon channel layers, the top FET module is disposed on the MDI film, the top FET module contains a plurality of the first silicon germanium layers and the silicon channel layers, wherein three of the first silicon germanium layers are alternately stacked with three of the silicon channel layers. The MDI film contains a plurality of the first silicon germanium layers and second silicon germanium layers, wherein three of the second silicon germanium layers are alternately stacked with two of the first silicon germanium layers, and wherein the second silicon germanium layers have a greater germanium concentration than the first silicon germanium layers. The MDI film further contains a bottom silicon epi layer disposed between the bottom FET module and the plurality of the first silicon germanium layers and the second silicon germanium layers and a top silicon epi layer disposed between the top FET module and the plurality of the first silicon germanium layers and the second silicon germanium layers.

In other embodiments, a method of fabricating a film stack is provided and includes depositing a FET module on a substrate, depositing an MDI film on the bottom FET module, and depositing a top FET module on the MDI film. The bottom FET module contains a plurality of first silicon germanium layers and silicon channel layers, wherein the first silicon germanium layers and the silicon channel layers are alternately stacked on each other. The top FET module contains a plurality of the first silicon germanium layers and the silicon channel layers, wherein the first silicon germanium layers and the silicon channel layers are alternately stacked on each other. The MDI film contains a plurality of the first silicon germanium layers and second silicon germanium layers, wherein the first silicon germanium layers the second silicon germanium layers are alternately stacked on each other, and wherein the second silicon germanium layers have a greater germanium concentration than the first silicon germanium layers. The MDI film also contains a bottom silicon epi layer disposed between the bottom FET module and the plurality of the first silicon germanium layers and the second silicon germanium layers and a top silicon epi layer disposed between the top FET module and the plurality of the first silicon germanium layers and the second silicon germanium layers. The method further includes depositing a pad oxide layer containing silicon oxide on the top FET module, depositing a nitride layer containing silicon nitride on the pad oxide layer, and forming a plurality of features separated by trenches and disposed on the substrate by etching the trenches through at least the nitride layer, the pad oxide layer, the top FET module, the MDI film, and the bottom FET module during an etching process, wherein each of the trenches has an aspect ratio of greater than 10, and wherein each of the features contains a multi-layered epitaxial stack containing the MDI film disposed between the FET module and the top FET module, the pad oxide layer disposed on the top FET module, and the nitride layer disposed on the pad oxide layer.

In one or more embodiments, a workpiece is provided and contains a plurality of features separated by trenches and disposed on a substrate, wherein each of the trenches has an aspect ratio of greater than 10, and wherein each of the features contains a multi-layered epitaxial stack containing an MDI film disposed between a FET module and a top FET module. The bottom FET module is disposed on the substrate and contains a plurality of first silicon germanium layers and silicon channel layers, wherein the first silicon germanium layers and the silicon channel layers are alternately stacked on each other. The top FET module is disposed on the MDI film and contains a plurality of the first silicon germanium layers and the silicon channel layers, wherein the first silicon germanium layers and the silicon channel layers are alternately stacked on each other. The MDI film contains a second silicon germanium layer containing a concentration of germanium greater than the first silicon germanium layers and greater than 25 atomic percent (at %). The MDI film also contains a bottom silicon epi layer disposed between the bottom FET module and the second silicon germanium layer and a top silicon epi layer disposed between the top FET module and second silicon germanium layer.

In some embodiments, a workpiece is provided and contains a plurality of features separated by trenches and disposed on a substrate, wherein each of the trenches has an aspect ratio of greater than 10, and wherein each of the features contains a multi-layered epitaxial stack containing an MDI film disposed between a FET module and a top FET module. The bottom FET module is disposed on the substrate and contains a plurality of first silicon germanium layers and silicon channel layers, wherein four of the first silicon germanium layers are alternately stacked with three of the silicon channel layers. The top FET module is disposed on the MDI film and contains a plurality of the first silicon germanium layers and the silicon channel layers, wherein three of the first silicon germanium layers are alternately stacked with three of the silicon channel layers. The MDI film contains a second silicon germanium layer containing a concentration of germanium greater than the first silicon germanium layers and greater than 25 at %. The MDI film also contains a bottom silicon epi layer disposed between the bottom FET module and the second silicon germanium layer and a top silicon epi layer disposed between the top FET module and the second silicon germanium layer.

In other embodiments, a method of fabricating a film stack is provided and includes depositing a FET module on a substrate, depositing an MDI film on the bottom FET module, and depositing a top FET module on the MDI film. The bottom FET module contains a plurality of first silicon germanium layers and silicon channel layers, wherein the first silicon germanium layers and the silicon channel layers are alternately stacked on each other. The top FET module contains a plurality of the first silicon germanium layers and the silicon channel layers, wherein the first silicon germanium layers and the silicon channel layers are alternately stacked on each other. The MDI film contains a second silicon germanium layer containing a concentration of germanium greater than the first silicon germanium layers and greater than 25 at %. The MDI film also contains a bottom silicon epi layer disposed between the bottom FET module and the second silicon germanium layer and a top silicon epi layer disposed between the top FET module and the second silicon germanium layer. The method further includes depositing a pad oxide layer containing silicon oxide on the top FET module, depositing a nitride layer containing silicon nitride on the pad oxide layer, and forming a plurality of features separated by trenches and disposed on the substrate by etching the trenches through at least the nitride layer, the pad oxide layer, the top FET module, the MDI film, and the bottom FET module during an etching process. Each of the trenches has an aspect ratio of greater than 10, and each of the features contains a multi-layered epitaxial stack containing the MDI film disposed between the FET module and the top FET module, the pad oxide layer disposed on the top FET module, and the nitride layer disposed on the pad oxide layer.

### DETAILED DESCRIPTION

Embodiments of the present disclosure relate to the field of electronic device manufacturing, and in particular, to transistors. More particularly, embodiments of the disclosure are directed to multi-layered epitaxial stacks, such as complementary field-effect-transistors (cFETs), as well as the related fabrication processes. The method may be used to fabricate a layered middle dielectric isolation (MDI) structure and carbon-doping of epitaxially grown silicon germanium (SiGe) layers together in the cFETs. In some embodiments, by integrating a layered MDI structure together with carbon-doping of SiGe layers into the cFETs, relaxation, wafer bow, and defects in a stack have been significantly reduced when compared to traditional stacks. This leads to fully-strained stacks with “zero” defectivity as measured using XRDI within the scope of the tool. Advantageously, taller multi-layered epitaxial stacks incorporate a greater number of silicon channels (e.g., pMOS and nMOS channels) when compared to traditional stacks. Furthermore, the selectivity in the downstream processes is improved by an order of magnitude. As such, the trenches separating the features have high aspect ratios (e.g., greater than 10), such that each feature includes the multi-layered epitaxial stack containing the MDI film disposed between the top and bottom FET modules.

In one or more embodiments, a workpiece is provided and contains a multi-layered epitaxial stack disposed on a substrate and containing a middle dielectric isolation (MDI) film disposed between a bottom field effect transistor (FET) module and a top FET module. The bottom FET module is disposed on the substrate and contains a plurality of first silicon germanium layers and silicon channel layers. The first silicon germanium layers and the silicon channel layers are alternately stacked on each other. The top FET module is disposed on the MDI film and contains a plurality of the first silicon germanium layers and the silicon channel layers. The first silicon germanium layers and the silicon channel layers are alternately stacked on each other.

In some embodiments, the MDI film contains a plurality of the first silicon germanium layers and second silicon germanium layers, where the first silicon germanium layers the second silicon germanium layers are alternately stacked on each other. The second silicon germanium layers have a greater germanium concentration than the first silicon germanium layers. The MDI film further contains two silicon epi layers, a bottom silicon epi layer and a top silicon epi layer. The bottom silicon epi layer is disposed between the bottom FET module and the plurality of the first silicon germanium layers and the second silicon germanium layers. The top silicon epi layer is disposed between the top FET module and the plurality of the first silicon germanium layers and the second silicon germanium layers.

In other embodiments, the MDI film contains a second silicon germanium layer containing a concentration of germanium greater than the first silicon germanium layers and greater than 25 atomic percent (at %). The MDI film further contains two silicon epi layers, a bottom silicon epi layer and a top silicon epi layer, separated by the MDI film. The bottom silicon epi layer is disposed between the bottom FET module and the plurality of the first silicon germanium layers and the second silicon germanium layers. The top silicon epi layer disposed between the top FET module and the plurality of the first silicon germanium layers and the second silicon germanium layers.

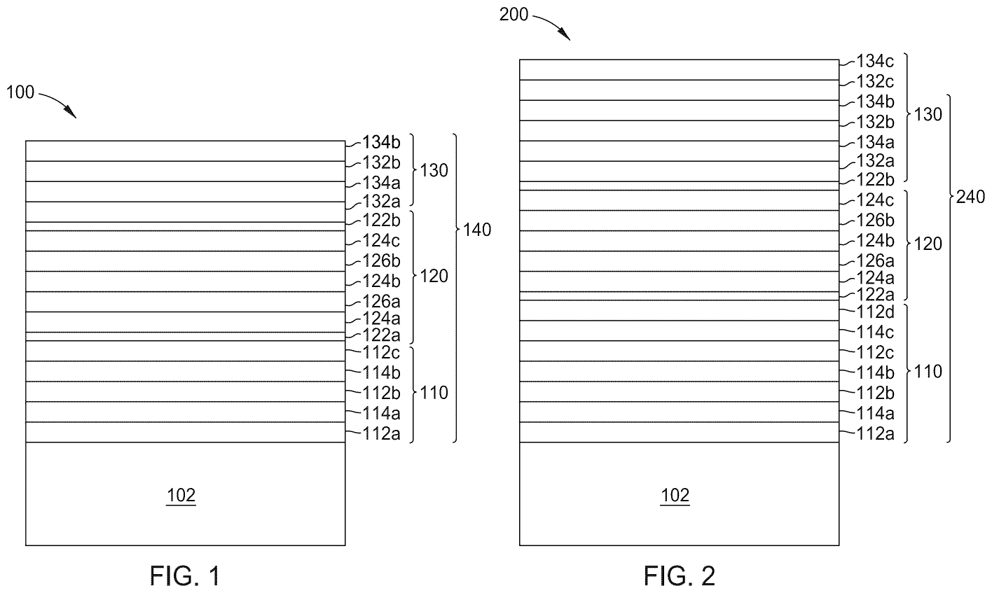

FIG. 1 depicts a multi-layered epitaxial stack 140, such as a complementary field-effect-transistor (cFET) stack, according to one or more embodiments described and discussed herein. A workpiece 100 is provided and contains the multi-layered epitaxial stack 140 disposed on a substrate 102. An MDI film 120 is disposed between a bottom FET module 110 and a top FET module 130. In one or more embodiments, each of the bottom FET module 110 and the top FET module 130 may independently be or contain a metal oxide semiconductor (MOS) film. The multi-layered epitaxial stack 140 is a cFET which may be further processed to form a plurality of features, such as a plurality of cFET components separated by trenches, vias, spaces, or other gaps, as will be further discussed below.

The bottom FET module 110 is disposed on the substrate 102. The bottom FET module 110 contains a plurality of first silicon germanium layers 112a, 112b, 112c (collectively 112) and silicon channel layers 114a, 114b (collectively 114). The first silicon germanium layers 112 and the silicon channel layers 114 are alternately stacked on each other throughout the bottom FET module 110. Although the bottom FET module 110 of the multi-layered epitaxial stack 140 is depicted with three of the first silicon germanium layers 112 and two of the silicon channel layers 114, in other embodiments, the bottom FET module 110 may contain 1, 2, 3, 4, 5, or more pairs of the first silicon germanium layers 112 and the silicon channel layers 114 and one additional first silicon germanium layer 112 alternately stacked on each other.

The top FET module 130 is disposed on the MDI film 120 and contains a plurality of the first silicon germanium layers 132a, 132b (collectively 132) and the silicon channel layers 134a, 134b (collectively 134). The first silicon germanium layers 132 and the silicon channel layers 134 are alternately stacked on each other throughout the top FET module 130. Although the top FET module 130 of the multi-layered epitaxial stack 140 is depicted with two of the first silicon germanium layers 132 and two of the silicon channel layers 134, in other embodiments, the top FET module 130 may contain 1, 2, 3, 4, 5, or more pairs of the first silicon germanium layers 132 and the silicon channel layers 134 alternately stacked on each other.

The MDI film 120 contains a bottom silicon epi layer 122a, a top silicon epi layer 122b, and a plurality of first silicon germanium layers 126a, 126b (collectively 126) and second silicon germanium layers 124a, 124b, 124c (collectively 124) alternately stacked on each other. The plurality of first silicon germanium layers 126 and the second silicon germanium layers is disposed between the bottom silicon epi layer 122a and the top silicon epi layer 122b. Although the MDI film 120 of the multi-layered epitaxial stack 140 is depicted with three of the second silicon germanium layers 124 and two of the first silicon germanium layers 126, in other embodiments, the MDI film 120 may contain 1, 2, 3, 4, 5, or more pairs of the second silicon germanium layers 124 and the first silicon germanium layers 132 with one additional second silicon germanium layer 124 alternately stacked on each other.

The first silicon germanium layers 126 and the second silicon germanium layers 124 are alternately stacked on each other throughout the MDI film 120. Both of the first silicon germanium layers 126 and the second silicon germanium layers 124 contain silicon, germanium, and an optional dopant, such as carbon. However, the second silicon germanium layers 124 have a greater germanium concentration than the first silicon germanium layers 126.

The bottom silicon epi layer 122a is disposed between the bottom FET module 110 and the plurality of the first silicon germanium layers 126 and the second silicon germanium layers 124. For example, the bottom silicon epi layer 122a is disposed between the bottom FET module 110 and the second silicon germanium layer 124b. The top silicon epi layer 122b is disposed between the top FET module 130 and the plurality of the first silicon germanium layers 126 and the second silicon germanium layers 124. For example, the top silicon epi layer 122b is disposed between the top FET module 130 and the second silicon germanium layer 124c.

In one or more embodiments, the plurality of first silicon germanium layers 112 and silicon channel layers 114 of the bottom FET module 110 contains three of the first silicon germanium layers 112 and two of the silicon channel layers 114 alternately stacked on each other, as depicted in FIG. 1. In some embodiments, the plurality of first silicon germanium layers 132 and silicon channel layers 134 of the top FET module 130 contains two of the first silicon germanium layers 132 and two of the silicon channel layers 134 alternately stacked on each other, as depicted in FIG. 1. In one or more embodiments, the plurality of the first silicon germanium layers 126 and second silicon germanium layers 124 of the MDI film 120 contains three of the second silicon germanium layers 124 and two of the first silicon germanium layers 126 alternately stacked on each other, as depicted in FIG. 1.

Each of the first silicon germanium layers 112, 126, 132 may independently have the same or different germanium concentration as each other. In one or more embodiments, each of the first silicon germanium layers 112, 126, 132 independently has a germanium concentration in a range from about 8 atomic percent (at %), about 10 at %, about 11 at %, or about 12 at % to about 13 at %, about 14 at %, about 15 at %, about 16 at %, about 17 at %, about 18 at %, about 19 at %, about 20 at %, about 22 at %, or greater. For example, each of the first silicon germanium layers 112, 126, 132 independently has a germanium concentration in a range from about 8 at % to about 22 at %, about 10 at % to about 20 at %, about 10 at % to about 18 at %, about 10 at % to about 16 at %, about 10 at % to about 15 at %, about 10 at % to about 14 at %, about 10 at % to about 12 at %, about 12 at % to about 20 at %, about 12 at % to about 18 at %, about 12 at % to about 16 at %, about 12 at % to about 15 at %, about 12 at % to about 14 at %, about 14 at % to about 20 at %, about 14 at % to about 18 at %, about 14 at % to about 16 at %, or about 14 at % to about 15 at %.

In one or more embodiments, each of the first silicon germanium layers 112, 126, 132 independently has a silicon concentration in a range from about 78 at %, about 80 at %, about 82 at %, about 84 at %, about 85 at %, about 86 at %, about 88 at %, about 90 at %, about 91 at %, about 92 at %, or greater. For example, each of the first silicon germanium layers 112, 126, 132 independently has a silicon concentration in a range from about 78 at % to about 92 at %, about 80 at % to about 90 at %, about 80 at % to about 88 at %, about 80 at % to about 86 at %, about 80 at % to about 85 at %, about 80 at % to about 84 at %, about 80 at % to about 82 at %, about 82 at % to about 90 at %, about 82 at % to about 88 at %, about 82 at % to about 86 at %, about 82 at % to about 85 at %, about 82 at % to about 84 at %, about 84 at % to about 90 at %, about 84 at % to about 88 at %, about 84 at % to about 86 at %, about 84 at % to about 85 at %, about 85 at % to about 90 at %, about 85 at % to about 88 at %, or about 85 at % to about 86 at %.

In one or more embodiments, each of the first silicon germanium layers 112, 126, 132 independently has a carbon concentration in a range from about 0.1 at %, about 0.2 at %, about 0.3 at %, about 0.4 at %, about 0.5 at %, about 0.6 at %, about 0.7 at %, about 0.8 at %, about 0.9 at %, about 1 at %, about 1.1 at %, about 1.2 at %, about 1.3 at %, about 1.4 at %, about 1.5 at %, or greater. For example, each of the first silicon germanium layers 112, 126, 132 independently has a carbon concentration in a range from about 0.1 at % to about 1.5 at %, about 0.2 at % to about 1 at %, about 0.2 at % to about 0.9 at %, about 0.2 at % to about 0.8 at %, about 0.2 at % to about 0.6 at %, about 0.2 at % to about 0.5 at %, about 0.2 at % to about 0.4 at %, about 0.2 at % to about 0.3 at %, about 0.3 at % to about 1 at %, about 0.3 at % to about 0.9 at %, about 0.3 at % to about 0.8 at %, about 0.3 at % to about 0.6 at %, about 0.3 at % to about 0.5 at %, about 0.3 at % to about 0.4 at %, about 0.4 at % to about 1 at %, about 0.4 at % to about 0.9 at %, about 0.4 at % to about 0.8 at %, about 0.4 at % to about 0.6 at %, about 0.4 at % to about 0.5 at %, about 0.5 at % to about 1 at %, about 0.5 at % to about 0.9 at %, about 0.5 at % to about 0.8 at %, about 0.5 at % to about 0.6 at %, about 0.6 at % to about 1 at %, about 0.6 at % to about 0.9 at %, about 0.6 at % to about 0.8 at %, or about 0.6 at % to about 0.7 at %.

In one or more embodiments, each of the first silicon germanium layers 112, 126, 132 independently has a thickness in a range from about 2 nm, about 4 nm, about 5 nm, about 6 nm, or about 8 nm to about 10 nm, about 12 nm, about 14 nm, about 15 nm, about 16 nm, about 18 nm, about 20 nm, or greater. For example, each of the first silicon germanium layers 112, 126, 132 independently has a thickness in a range from about 2 nm to about 20 nm, about 5 nm to about 15 nm, about 5 nm to about 14 nm, about 5 nm to about 12 nm, about 5 nm to about 10 nm, about 5 nm to about 8 nm, about 5 nm to about 6 nm, about 6 nm to about 15 nm, about 6 nm to about 14 nm, about 6 nm to about 12 nm, about 6 nm to about 10 nm, about 6 nm to about 8 nm, about 8 nm to about 15 nm, about 8 nm to about 14 nm, about 8 nm to about 12 nm, about 8 nm to about 10 nm, or about 8 nm to about 9 nm.

In one or more embodiments, each of the second silicon germanium layers 124 independently has a germanium concentration in a range from about or greater than 25 at %, about or greater than 28 at %, about or greater than 30 at %, about or greater than 32 at %, about or greater than 34 at %, about or greater than 35 at %, about or greater than 36 at %, about or greater than 38 at %, about or greater than 40 at %, about or greater than 42 at %, about or greater than 44 at %, about or greater than 45 at %, about or greater than 46 at %, about or greater than 46 at %, about or greater than 50 at %, about or greater than 52 at %, about or greater than 55 at %, or greater. For example, each of the second silicon germanium layers 124 independently has a germanium concentration in a range from about 25 at % to about 55 at %, about 30 at % to about 55 at %, about 30 at % to about 50 at %, about 30 at % to about 48 at %, about 30 at % to about 45 at %, about 30 at % to about 42 at %, about 30 at % to about 40 at %, about 30 at % to about 38 at %, about 30 at % to about 36 at %, about 30 at % to about 35 at %, about 30 at % to about 34 at %, about 30 at % to about 32 at %, about 32 at % to about 55 at %, about 32 at % to about 50 at %, about 32 at % to about 48 at %, about 32 at % to about 45 at %, about 32 at % to about 42 at %, about 32 at % to about 40 at %, about 32 at % to about 38 at %, about 32 at % to about 36 at %, about 32 at % to about 35 at %, about 32 at % to about 34 at %, about 34 at % to about 55 at %, about 34 at % to about 50 at %, about 34 at % to about 48 at %, about 34 at % to about 45 at %, about 34 at % to about 42 at %, about 34 at % to about 40 at %, about 34 at % to about 38 at %, about 34 at % to about 36 at %, about 34 at % to about 35 at %, about 38 at % to about 55 at %, about 38 at % to about 50 at %, about 38 at % to about 48 at %, about 38 at % to about 45 at %, about 38 at % to about 42 at %, about 38 at % to about 40 at %, about 40 at % to about 55 at %, about 40 at % to about 50 at %, about 40 at % to about 48 at %, about 40 at % to about 45 at %, or about 40 at % to about 42 at %.

In one or more embodiments, each of the second silicon germanium layers 124 independently has a silicon concentration in a range from about 50 at %, about 52 at %, about 54 at %, about 55 at %, about 56 at %, about 58 at %, about 60 at %, about 62 at %, about 64 at %, about 65 at %, about 66 at %, about 68 at %, about 70 at %, about 75 at %, or greater. For example, each of the second silicon germanium layers 124 independently has a silicon concentration in a range from about 50 at % to about 70 at %, about 50 at % to about 68 at %, about 50 at % to about 65 at %, about 50 at % to about 62 at %, about 50 at % to about 60 at %, about 50 at % to about 58 at %, about 50 at % to about 56 at %, about 50 at % to about 55 at %, about 50 at % to about 52 at %, about 52 at % to about 70 at %, about 52 at % to about 68 at %, about 52 at % to about 65 at %, about 52 at % to about 62 at %, about 52 at % to about 60 at %, about 52 at % to about 58 at %, about 52 at % to about 56 at %, about 52 at % to about 55 at %, about 54 at % to about 70 at %, about 54 at % to about 68 at %, about 54 at % to about 65 at %, about 54 at % to about 62 at %, about 54 at % to about 60 at %, about 54 at % to about 58 at %, about 54 at % to about 56 at %, about 54 at % to about 55 at %, about 56 at % to about 70 at %, about 56 at % to about 68 at %, about 56 at % to about 65 at %, about 56 at % to about 62 at %, about 56 at % to about 60 at %, about 58 at % to about 70 at %, about 58 at % to about 68 at %, about 58 at % to about 65 at %, about 58 at % to about 62 at %, or about 58 at % to about 60 at %.

In one or more embodiments, each of the second silicon germanium layers 124 independently has a carbon concentration in a range from about 0.1 at %, about 0.2 at %, about 0.3 at %, about 0.35 at % or about 0.4 at % to about 0.45 at %, about 0.5 at %, about 0.55 at %, about 0.6 at %, about 0.65 at %, about 0.7 at %, about 0.75 at %, about 0.8 at %, about 0.9 at %, about 1 at %, about 1.1 at %, about 1.2 at %, or greater. For example, each of the second silicon germanium layers 124 independently has a carbon concentration in a range from about 0.1 at % to about 1.2 at %, about 0.2 at % to about 1.2 at %, about 0.2 at % to about 1 at %, about 0.2 at % to about 0.8 at %, about 0.2 at % to about 0.7 at %, about 0.2 at % to about 0.6 at %, about 0.2 at % to about 0.5 at %, about 0.2 at % to about 0.4 at %, about 0.4 at % to about 1.2 at %, about 0.4 at % to about 1 at %, about 0.4 at % to about 0.8 at %, about 0.4 at % to about 0.7 at %, about 0.4 at % to about 0.6 at %, about 0.4 at % to about 0.5 at %, about 0.5 at % to about 1.2 at %, about 0.5 at % to about 1 at %, about 0.5 at % to about 0.8 at %, about 0.5 at % to about 0.7 at %, about 0.5 at % to about 0.6 at %, about 0.6 at % to about 1.2 at %, about 0.6 at % to about 1 at %, about 0.6 at % to about 0.8 at %, or about 0.6 at % to about 0.7 at %.

In one or more embodiments, each of the second silicon germanium layers 124 independently has a thickness in a range from a thickness in a range from about 2 nm, about 3 nm, about 4 nm, about 5 nm, about 6 nm, about 7 nm, or about 8 nm to about 9 nm, about 10 nm, about 12 nm, about 14 nm, about 15 nm, about 16 nm, about 18 nm, about 20 nm, or greater. For example, each of the second silicon germanium layers 124 independently has a thickness in a range from about 2 nm to about 20 nm, about 5 nm to about 15 nm, about 5 nm to about 14 nm, about 5 nm to about 12 nm, about 5 nm to about 10 nm, about 5 nm to about 8 nm, about 5 nm to about 6 nm, about 6 nm to about 15 nm, about 6 nm to about 14 nm, about 6 nm to about 12 nm, about 6 nm to about 10 nm, about 6 nm to about 8 nm, about 8 nm to about 15 nm, about 8 nm to about 14 nm, about 8 nm to about 12 nm, about 8 nm to about 10 nm, or about 8 nm to about 9 nm, about 4 nm to about 12 nm, about 6 nm to about 10 nm, or about 7 nm to about 9 nm.

In one or more embodiments, each of the silicon channel layers 114, 134 independently has a silicon concentration of about or greater than 95 at %, about or greater than 96 at %, about or greater than 97 at %, or about or greater than 98 at % to about or greater than 99 at %, about or greater than 99.5 at %, about or greater than 99.9 at %, or about 100 at %. For example, each of the silicon channel layers 114, 134 independently has a silicon concentration of about 95 at % to about 100%, about 95 at % to about 99.5%, about 95 at % to about 99%, about 95 at % to about 98.5%, about 95 at % to about 98%, about 95 at % to about 97%, about 95 at % to about 96%, about 97 at % to about 100%, about 97 at % to about 99.5%, about 97 at % to about 99%, about 97 at % to about 98.5%, about 97 at % to about 98%, about 99 at % to about 100%, or about 99 at % to about 99.5%.

In one or more embodiments, each of the silicon channel layers 114, 134 independently has a thickness in a range from a thickness in a range from about 2 nm, about 3 nm, about 4 nm, about 5 nm, about 6 nm, about 7 nm, or about 8 nm to about 9 nm, about 10 nm, about 12 nm, about 14 nm, about 15 nm, about 16 nm, about 18 nm, about 20 nm, or greater. For example, each of the silicon channel layers 114, 134 independently has a thickness in a range from about 2 nm to about 20 nm, about 5 nm to about 15 nm, about 5 nm to about 14 nm, about 5 nm to about 12 nm, about 5 nm to about 10 nm, about 5 nm to about 8 nm, about 5 nm to about 6 nm, about 6 nm to about 15 nm, about 6 nm to about 14 nm, about 6 nm to about 12 nm, about 6 nm to about 10 nm, about 6 nm to about 8 nm, about 8 nm to about 15 nm, about 8 nm to about 14 nm, about 8 nm to about 12 nm, about 8 nm to about 10 nm, or about 8 nm to about 9 nm, about 4 nm to about 12 nm, about 6 nm to about 10 nm, or about 7 nm to about 9 nm.

In one or more embodiments, each of the bottom silicon epi layers 122a and the top silicon epi layers 122b independently has a silicon concentration of about or greater than 95 at %, about or greater than 96 at %, about or greater than 97 at %, or about or greater than 98 at % to about or greater than 99 at %, about or greater than 99.5 at %, about or greater than 99.9 at %, or about 100 at %. For example, each of the bottom silicon epi layers 122a and the top silicon epi layers 122b independently has a silicon concentration of about 95 at % to about 100%, about 95 at % to about 99.5%, about 95 at % to about 99%, about 95 at % to about 98.5%, about 95 at % to about 98%, about 95 at % to about 97%, about 95 at % to about 96%, about 97 at % to about 100%, about 97 at % to about 99.5%, about 97 at % to about 99%, about 97 at % to about 98.5%, about 97 at % to about 98%, about 99 at % to about 100%, or about 99 at % to about 99.5%.

In one or more embodiments, each of the bottom silicon epi layers 122a and the top silicon epi layers 122b independently has a thickness in a range from about 0.5 nm, about 0.8 nm, about 1 nm, about 1.2 nm, about 1.5 nm, about 1.8 nm, about 2 nm, about 2.2 nm, about 2.5 nm, about 2.8 nm, about 3 nm, about 3.2 nm, about 3.5 nm, about 3.8 nm, about 4 nm, about 4.2 nm, about 4.5 nm, about 4.8 nm, about 5 nm, or greater. For example, each of the bottom silicon epi layers 122a and the top silicon epi layers 122b independently has a thickness in a range from about 0.5 nm to about 5 nm, about 0.5 nm to about 4 nm, about 0.5 nm to about 3.5 nm, about 0.5 nm to about 3 nm, about 0.5 nm to about 2.5 nm, about 0.5 nm to about 2 nm, about 0.5 nm to about 1.5 nm, about 0.5 nm to about 1 nm, about 1 nm to about 5 nm, about 1 nm to about 4 nm, about 1 nm to about 3.5 nm, about 1 nm to about 3 nm, about 1 nm to about 2.5 nm, about 1 nm to about 2 nm, about 1 nm to about 1.5 nm, about 1.5 nm to about 5 nm, about 1.5 nm to about 4 nm, about 1.5 nm to about 3.5 nm, about 1.5 nm to about 3 nm, about 1.5 nm to about 2.5 nm, about 1.5 nm to about 2 nm, about 1.5 nm to about 1.8 nm, about 2 nm to about 5 nm, about 2 nm to about 4 nm, about 2 nm to about 3.5 nm, about 2 nm to about 3 nm, about 2 nm to about 2.5 nm, or about 2 nm to about 2.2 nm.

In one or more embodiments, each of the bottom and top FET modules 110, 130 of the multi-layered epitaxial stack 140 independently has a thickness in a range from about 20 nm, about 25 nm, about 30 nm, about 35 nm or about 40 nm to about 45 nm, about 50 nm, about 55 nm, about 60 nm, about 65 nm, about 70 nm, about 75 nm, about 80 nm, about 85 nm, about 90 nm, about 100 nm, or greater. For example, each of the bottom and top FET modules 110, 130 of the multi-layered epitaxial stack 140 independently has a thickness in a range from about 20 nm to about 70 nm, about 20 nm to about 60 nm, about 20 nm to about 55 nm, about 20 nm to about 50 nm, about 20 nm to about 45 nm, about 20 nm to about 40 nm, about 20 nm to about 30 nm, about 30 nm to about 70 nm, about 30 nm to about 60 nm, about 30 nm to about 55 nm, about 30 nm to about 50 nm, about 30 nm to about 45 nm, about 30 nm to about 40 nm, about 30 nm to about 35 nm, about 40 nm to about 70 nm, about 40 nm to about 60 nm, about 40 nm to about 55 nm, about 40 nm to about 50 nm, about 40 nm to about 45 nm, about 50 nm to about 70 nm, about 50 nm to about 60 nm, or about 50 nm to about 55 nm.

In one or more examples of the multi-layered epitaxial stack 140, the bottom FET module 110 has a thickness in a range from about 30 nm to about 70 nm, and the top FET module 130 has a thickness in a range from about 20 nm to about 60 nm. In other examples, the bottom FET module 110 has a thickness in a range from about 40 nm to about 60 nm, and the top FET module 130 has a thickness in a range from about 30 nm to about 50 nm. In some examples, the bottom FET module 110 has a thickness in a range from about 45 nm to about 55 nm, and the top FET module 130 has a thickness in a range from about 35 nm to about 45 nm. In one or more examples, the bottom FET module 110 has a thickness of about 50 nm and the top FET module 130 has a thickness of about 40 nm.

In one or more embodiments, the MDI film 120 of the multi-layered epitaxial stack 140 has a thickness in a range from about 20 nm, about 25 nm, about 30 nm, about 35 nm, about 40 nm, about 42 nm, or about 45 nm to about 48 nm, about 50 nm, about 52 nm, about 55 nm, about 60 nm, about 65 nm, about 70 nm, about 75 nm, about 80 nm, about 85 nm, about 90 nm, about 100 nm, or greater. For example, the MDI film 120 has a thickness in a range from about 35 nm to about 65 nm, about 35 nm to about 60 nm, about 35 nm to about 55 nm, about 35 nm to about 50 nm, about 35 nm to about 48 nm, about 35 nm to about 45 nm, about 35 nm to about 40 nm, about 40 nm to about 65 nm, about 40 nm to about 60 nm, about 40 nm to about 55 nm, about 40 nm to about 50 nm, about 40 nm to about 48 nm, about 40 nm to about 45 nm, about 40 nm to about 42 nm, about 45 nm to about 65 nm, about 45 nm to about 60 nm, about 45 nm to about 55 nm, about 45 nm to about 50 nm, about 45 nm to about 48 nm, about 48 nm to about 65 nm, about 48 nm to about 60 nm, about 48 nm to about 55 nm, about 48 nm to about 50 nm, about 50 nm to about 65 nm, about 50 nm to about 60 nm, or about 50 nm to about 55 nm.

In one or more embodiments, the multi-layered epitaxial stack 140 has a thickness in a range from about 100 nm, about 110 nm, about 120 nm, about 125 nm, about 130 nm, or about 135 nm to about 138 nm, about 140 nm, about 142 nm, about 145 nm, about 150 nm, about 155 nm, about 160 nm, about 170 nm, about 180 nm, about 190 nm, about 200 nm, or greater. For example, the multi-layered epitaxial stack 140 has a thickness in a range from about 100 nm to about 200 nm, about 120 nm to about 180 nm, about 120 nm to about 160 nm, about 120 nm to about 155 nm, about 120 nm to about 150 nm, about 120 nm to about 145 nm, about 120 nm to about 140 nm, about 120 nm to about 138 nm, about 120 nm to about 135 nm, about 120 nm to about 130 nm, about 120 nm to about 125 nm, about 130 nm to about 180 nm, about 130 nm to about 160 nm, about 130 nm to about 155 nm, about 130 nm to about 150 nm, about 130 nm to about 145 nm, about 130 nm to about 140 nm, about 130 nm to about 138 nm, about 130 nm to about 135 nm, about 130 nm to about 132 nm, about 135 nm to about 180 nm, about 135 nm to about 160 nm, about 135 nm to about 155 nm, about 135 nm to about 150 nm, about 135 nm to about 145 nm, about 135 nm to about 140 nm, about 135 nm to about 138 nm, about 140 nm to about 180 nm, about 140 nm to about 160 nm, about 140 nm to about 155 nm, about 140 nm to about 150 nm, about 140 nm to about 145 nm, or about 140 nm to about 142 nm.

In one or more embodiments, the multi-layered epitaxial stack 140 has a wafer bow in a range from about 40 μm, about 45 μm, or about 50 μm to about 55 μm, about 60 μm, about 65 μm, or about 70 μm. For example, the multi-layered epitaxial stack 140 has a wafer bow in a range from about 40 μm to about 70 μm, about 50 μm to about 70 μm, about 60 μm to about 70 μm, about 40 μm to about 60 μm, about 50 μm to about 60 μm, such as about 55 μm.

In one or more examples, a top interface of the bottom FET module 110 contains the first silicon germanium layer 112c having an abruptness value in a range from about 1.1 nm to about 1.4 nm, about 1.15 nm to about 1.3 nm, about 1.18 nm to about 1.25 nm, about 1.19 nm to about 1.23 nm, about 1.20 nm to about 1.22 nm, about 1.21 nm. In some examples, a bottom interface of the bottom FET module 110 contains the first silicon germanium layer 112a having an abruptness value in a range from about 1.0 nm to about 1.3 nm, about 1.05 nm to about 1.25 nm, about 1.08 nm to about 1.15 nm, about 1.09 nm to about 1.12 nm, about 1.10 nm.

In one or more examples, a bottom interface of the top FET module 130 contains the first silicon germanium layer 132a having an abruptness value in a range from about 1.0 nm to about 1.3 nm, about 1.03 nm to about 1.28 nm, about 1.05 nm to about 1.25 nm, about 1.1 nm to about 1.2 nm, or about 1.11 nm. In some examples, a top interface of the top FET module 130 contains the silicon channel layer 134b having an abruptness value in a range from about 1.0 nm to about 1.3 nm, about 1.03 nm to about 1.28 nm, about 1.05 nm to about 1.25 nm, about 1.1 nm to about 1.2 nm, or about 1.14 nm.

In one or more embodiments, the workpiece 100 is provided and contains a multi-layered epitaxial stack 140 disposed on a substrate 102 and containing an MDI film 120 disposed between a bottom FET module 110 and a top FET module 130. The bottom FET module 110 is disposed on the substrate 102 and contains a plurality of first silicon germanium layers 112 and silicon channel layers 114, where three of the first silicon germanium layers 112a, 112b, 112c are alternately stacked with two of the silicon channel layers 114a, 114b. The top FET module 130 is disposed on the MDI film 120 and contains a plurality of the first silicon germanium layers 132 and the silicon channel layers 134, and where two of the first silicon germanium layers 132a, 132b are alternately stacked with two of the silicon channel layers 134a, 134b. The MDI film 120 contains a plurality of the first silicon germanium layers 126 and second silicon germanium layers 124, where three of the second silicon germanium layers 124a, 124b, 124c are alternately stacked with two of the first silicon germanium layers 126a, 126b. The second silicon germanium layers 124 have a greater germanium concentration than the first silicon germanium layers 112, 126, 132. The MDI film 120 further contains a bottom silicon epi layer 122a disposed between the bottom FET module 110 and the plurality of the first silicon germanium layers 126 and the second silicon germanium layers 124 and a top silicon epi layer 122b disposed between the top FET module 130 and the plurality of the first silicon germanium layers 126 and the second silicon germanium layers 124.

In one or more embodiments, a method of fabricating a film stack, including the multi-layered epitaxial stack 140, is provided and includes depositing a bottom FET module 110 on a substrate 102 at a first temperature during a first epi process, depositing an MDI film 120 on the bottom FET module 110 at a second temperature during a second epi process, and depositing a top FET module 130 on the MDI film 120 at a third temperature during third epi process. In some embodiments, each of the first, second, and third temperatures is independently in a range from about 575° C., about 580° C., about 585° C., about 590° C., or about 595° C. to about 596° C., about 597° C., about 598° C., about 599° C., about 600° C., about 601° C., about 602° C., about 603° C., about 604° C., about 605° C., about 610° C., about 615° C., about 620° C., about 625° C., about 630° C., about 635° C., or greater. For example, each of the first, second, and third temperatures is independently in a range from about 575° C. to about 625° C., about 575° C. to about 620° C., about 575° C. to about 615° C., about 575° C. to about 610° C., about 575° C. to about 605° C., about 575° C. to about 600° C., about 575° C. to about 595° C., about 575° C. to about 590° C., about 575° C. to about 585° C., about 575° C. to about 580° C., about 590° C. to about 625° C., about 590° C. to about 620° C., about 590° C. to about 615° C., about 590° C. to about 610° C., about 590° C. to about 605° C., about 590° C. to about 600° C., about 590° C. to about 595° C., about 595° C. to about 625° C., about 595° C. to about 620° C., about 595° C. to about 615° C., about 595° C. to about 610° C., about 595° C. to about 605° C., about 595° C. to about 600° C., about 595° C. to about 598° C., or about 595° C. to about 599° C.

In one or more examples, each of the first, second, and third temperatures is independently in a range from about 575° C. to about 625° C. In some examples, each of the first, second, and third temperatures is independently in a range from about 585° C. to about 615° C. In other examples, each of the first, second, and third temperatures is independently in a range from about 590° C. to about 610° C. In some examples, each of the first, second, and third temperatures is independently in a range from about 595° C. to about 605° C. In other examples, each of the first, second, and third temperatures is independently about 600° C.

The bottom FET module 110 contains a plurality of first silicon germanium layers 112 and silicon channel layers 114. The first silicon germanium layers 112 and the silicon channel layers 114 are alternately stacked on each other. The top FET module 130 contains a plurality of the first silicon germanium layers 132 and the silicon channel layers 134. The first silicon germanium layers 132 and the silicon channel layers 134 are alternately stacked on each other. The MDI film 120 contains bottom silicon epi layer 122a and the top silicon epi layer 122b are separated by a plurality of the first silicon germanium layers 126 and second silicon germanium layers 124. The first silicon germanium layers 126 and the second silicon germanium layers 124 are alternately stacked on each other. The second silicon germanium layers 124 have a greater germanium concentration than the first silicon germanium layers 112, 126, 132. The bottom silicon epi layer 122a is disposed between the bottom FET module 110 and the plurality of the first silicon germanium layers 126 and the second silicon germanium layers 124. The top silicon epi layer 122b is disposed between the top FET module 130 and the plurality of the first silicon germanium layers 126 and the second silicon germanium layers 124. In one or more examples, each of the first silicon germanium layers 112, 126, 132 and each the second silicon germanium layers 124 independently contain carbon.

In one or more embodiments, each of the first silicon germanium layers 112, 126, 132 and each the second silicon germanium layers 124 are independently deposited from one or more deposition gases containing various precursors by vapor deposition processes, such as epitaxial processes. The deposition gas for depositing the first silicon germanium layers 112, 126, 132 and/or the second silicon germanium layers 124 contains hydrogen (H₂), one or more silicon precursors, one or more silicon chlorine precursors, one or more silicon carbon precursors, and one or more germanium precursors. The deposition gas for depositing the second silicon germanium layers 124 contains a greater concentration of one or more germanium precursors relative to the deposition gas for depositing the first silicon germanium layers 112, 126, 132. In some examples, the deposition gas for depositing the second silicon germanium layers 124 contains a germanium precursor concentration at ratio of about 5:1, about 8:1, about 10:1, about 12:1, or about 15:1 over a germanium precursor concentration for depositing the first silicon germanium layers 112, 126, 132. In one or more examples, deposition gas for depositing the first silicon germanium layers 112, 126, 132 and/or the second silicon germanium layers 124 contains hydrogen, silane, dichlorosilane (DCS), germane, and monomethyl silane (MMS).

In one or more examples, the first silicon germanium layers 112, 126, 132 may be deposited by an epitaxial process with a deposition gas containing hydrogen at a flow rate in a range from about 8 slm (standard liters per minute) to about 12 slm, a silicon precursor (e.g., silane) at a flow rate in a range from about 150 sccm (standard cubic centiliters per minute) to about 200 sccm, a silicon chlorine precursor (e.g., DCS) at a flow rate in a range from about 80 sccm to about 120 sccm, a silicon carbon precursor (e.g., MMS) at a flow rate in a range from about 40 sccm to about 80 sccm, and a germanium precursor (e.g., germane) at a flow rate in a range from about 25 sccm to about 35 sccm. The temperature may be in a range from about 580° C. to about 620° C. and the pressure may be maintained in a range from about 10 Torr to about 30 Torr.

In some examples, the second silicon germanium layers 124 may be deposited by an epitaxial process with a deposition gas containing hydrogen at a flow rate in a range from about 10 slm to about 16 slm, a silicon precursor (e.g., silane) at a flow rate in a range from about 150 sccm to about 200 sccm, a silicon chlorine precursor (e.g., DCS) at a flow rate in a range from about 80 sccm to about 120 sccm, a silicon carbon precursor (e.g., MMS) at a flow rate in a range from about 40 sccm to about 80 sccm, and a germanium precursor (e.g., germane) at a flow rate in a range from about 300 sccm to about 500 sccm. The temperature may be in a range from about 580° C. to about 620° C. and the pressure may be maintained in a range from about 10 Torr to about 30 Torr.

In one or more other embodiments, each of the silicon channel layers 114, 134 is independently deposited from a deposition gas by an epitaxial process, and the deposition gas contains hydrogen (H₂) and one or more silicon precursors (e.g., silane). Also, each of the bottom silicon epi layers 122a and each the top silicon epi layer 122b are independently deposited from a deposition gas by an epitaxial process, and the deposition gas contains hydrogen (H₂) and one or more silicon precursors (e.g., silane).

In one or more examples, the silicon channel layers 114, 134, the bottom silicon epi layers 122a, and/or the top silicon epi layer 122b may be deposited by an epitaxial process with a deposition gas containing hydrogen at a flow rate in a range from about 8 slm to about 12 slm and a silicon precursor (e.g., silane) at a flow rate in a range from about 150 sccm to about 200 sccm. The temperature may be in a range from about 580° C. to about 620° C. and the pressure may be maintained in a range from about 10 Torr to about 30 Torr.

FIG. 2 depicts a multi-layered epitaxial stack 240, such as a cFET stack, according to one or more embodiments described and discussed herein. A workpiece 200 is provided and contains the multi-layered epitaxial stack 240 disposed on a substrate 102. An MDI film 120 is disposed between a bottom FET module 110 and a top FET module 130. In one or more embodiments, each of the bottom FET module 110 and the top FET module 130 may independently be or contain an MOS film. The multi-layered epitaxial stack 240 is a cFET which may be further processed to form a plurality of features, such as a plurality of cFET components separated by trenches, vias, spaces, or other gaps, as will be further discussed below.

In one or more embodiments, the multi-layered epitaxial stack 240 contains the same MDI film 120 as discussed and described for the multi-layered epitaxial stack 140. For example, the MDI film 120 contains three of the second silicon germanium layers 124 (e.g., 124a-124c) and two of the first silicon germanium layers 126 (e.g., 126a-126b) alternately stacked on each other. However, the multi-layered epitaxial stack 240 contains additional layers of the first silicon germanium layer 112, 132 and the silicon channel layers 114, 134 in the respective the bottom FET module 110 and the top FET module 130. For example, the bottom FET module 110 contains four of the first silicon germanium layers 112 (e.g., 112a-112d) and three of the silicon channel layers 114 (e.g., 114a-114c) alternately stacked on each other. Also, the top FET module 130 contains three of the first silicon germanium layers 132 (e.g., 132a-132c) and three of the silicon channel layers 134 (e.g., 134a-134c) alternately stacked on each other. The properties, compositions, layer thicknesses, and other attributes for the first silicon germanium layers 112, 126, 132, the second silicon germanium layers 124, the silicon channel layers 114, 134, the bottom silicon epi layers 122a, and the top silicon epi layers 122b have been described and discussed above.

In one or more embodiments, each of the bottom and top FET modules 110, 130 of the multi-layered epitaxial stack 240 independently has a thickness in a range from about 30 nm, about 35 nm, about 40 nm, about 45 nm, about 50 nm, about 55 nm, or about 60 nm to about 65 nm, about 70 nm, about 75 nm, about 80 nm, about 85 nm, about 90 nm, about 100 nm, about 110 nm, about 120 nm, about 130 nm, or greater. For example, each of the bottom and top FET modules 110, 130 of the multi-layered epitaxial stack 240 independently has a thickness in a range from about 40 nm to about 120 nm, about 40 nm to about 100 nm, about 40 nm to about 90 nm, about 40 nm to about 80 nm, about 40 nm to about 75 nm, about 40 nm to about 70 nm, about 40 nm to about 65 nm, about 40 nm to about 60 nm, about 40 nm to about 55 nm, about 40 nm to about 50 nm, about 50 nm to about 120 nm, about 50 nm to about 100 nm, about 50 nm to about 90 nm, about 50 nm to about 80 nm, about 50 nm to about 75 nm, about 50 nm to about 70 nm, about 50 nm to about 65 nm, about 50 nm to about 60 nm, about 50 nm to about 55 nm, about 60 nm to about 120 nm, about 60 nm to about 100 nm, about 60 nm to about 90 nm, about 60 nm to about 80 nm, about 60 nm to about 75 nm, about 60 nm to about 70 nm, about 60 nm to about 65 nm, about 70 nm to about 120 nm, about 70 nm to about 100 nm, about 70 nm to about 90 nm, about 70 nm to about 80 nm, or about 70 nm to about 75 nm.

In one or more examples, the bottom FET module 110 of the multi-layered epitaxial stack 240 has a thickness in a range from about 50 nm to about 90 nm, and the top FET module 130 of the multi-layered epitaxial stack 240 has a thickness in a range from about 40 nm to about 80 nm. In other examples, the bottom FET module 110 has a thickness in a range from about 60 nm to about 80 nm, and the top FET module 130 has a thickness in a range from about 50 nm to about 70 nm. In some examples, the bottom FET module 110 has a thickness in a range from about 65 nm to about 75 nm, and the top FET module 130 has a thickness in a range from about 55 nm to about 65 nm. In one or more examples, the bottom FET module 110 has a thickness of about 70 nm and the top FET module 130 has a thickness of about 60 nm.

In one or more embodiments, the MDI film 120 of the multi-layered epitaxial stack 240 has a thickness in a range from about 20 nm, about 25 nm, about 30 nm, about 35 nm, about 40 nm, about 42 nm, or about 45 nm to about 48 nm, about 50 nm, about 52 nm, about 55 nm, about 60 nm, about 65 nm, about 70 nm, about 75 nm, about 80 nm, about 85 nm, about 90 nm, about 100 nm, or greater. For example, the MDI film 120 of the multi-layered epitaxial stack 240 has a thickness in a range from about 35 nm to about 65 nm, about 35 nm to about 60 nm, about 35 nm to about 55 nm, about 35 nm to about 50 nm, about 35 nm to about 48 nm, about 35 nm to about 45 nm, about 35 nm to about 40 nm, about 40 nm to about 65 nm, about 40 nm to about 60 nm, about 40 nm to about 55 nm, about 40 nm to about 50 nm, about 40 nm to about 48 nm, about 40 nm to about 45 nm, about 40 nm to about 42 nm, about 45 nm to about 65 nm, about 45 nm to about 60 nm, about 45 nm to about 55 nm, about 45 nm to about 50 nm, about 45 nm to about 48 nm, about 48 nm to about 65 nm, about 48 nm to about 60 nm, about 48 nm to about 55 nm, about 48 nm to about 50 nm, about 50 nm to about 65 nm, about 50 nm to about 60 nm, or about 50 nm to about 55 nm.

In one or more embodiments, the multi-layered epitaxial stack 240 has a thickness in a range from about 100 nm, about 120 nm, about 130 nm, about 140 nm, about 150 nm, about 160 nm, about 170 nm, about 180 nm, about 190 nm, about 200 nm, about 210 nm, about 220 nm, about 240 nm, about 250 nm, about 260 nm, about 280 nm, about 300 nm, or greater. For example, the multi-layered epitaxial stack 240 has a thickness in a range from about 100 nm to about 300 nm, about 130 nm to about 280 nm, about 130 nm to about 250 nm, about 130 nm to about 220 nm, about 130 nm to about 200 nm, about 130 nm to about 190 nm, about 130 nm to about 180 nm, about 130 nm to about 178 nm, about 130 nm to about 175 nm, about 130 nm to about 170 nm, about 130 nm to about 165 nm, about 130 nm to about 160 nm, about 130 nm to about 155 nm, about 130 nm to about 150 nm, about 130 nm to about 140 nm, about 150 nm to about 280 nm, about 150 nm to about 250 nm, about 150 nm to about 220 nm, about 150 nm to about 200 nm, about 150 nm to about 190 nm, about 150 nm to about 180 nm, about 150 nm to about 178 nm, about 150 nm to about 175 nm, about 150 nm to about 170 nm, about 150 nm to about 165 nm, about 150 nm to about 160 nm, about 150 nm to about 155 nm, about 160 nm to about 280 nm, about 160 nm to about 250 nm, about 160 nm to about 220 nm, about 160 nm to about 200 nm, about 160 nm to about 190 nm, about 160 nm to about 180 nm, about 160 nm to about 178 nm, about 160 nm to about 175 nm, about 160 nm to about 170 nm, or about 160 nm to about 165 nm.

In one or more embodiments, the MDI film 120 of the multi-layered epitaxial stack 240 has a crystalline defect density in a range from about 0 pixels/cm², about or less than 10 pixels/cm², about or less than 50 pixels/cm², about or less than 80 pixels/cm², about or less than 100 pixels/cm², about or less than 120 pixels/cm², or about or less than 150 pixels/cm² to about or less than 158 pixels/cm², about or less than 160 pixels/cm², about or less than 170 pixels/cm², about or less than 180 pixels/cm², about or less than 200 pixels/cm², about or less than 250 pixels/cm², about or less than 300 pixels/cm², about or less than 350 pixels/cm², about or less than 400 pixels/cm², about or less than 500 pixels/cm², about or less than 600 pixels/cm², about or less than 800 pixels/cm², about or less than 1,000 pixels/cm², about or less than 1,500 pixels/cm², about or less than 2,000 pixels/cm², about or less than 3,000 pixels/cm², about or less than 4,000 pixels/cm², about or less than 5,000 pixels/cm², about or less than 6,000 pixels/cm², about or less than 8,000 pixels/cm², or about or less than 10,000 pixels/cm², as measured by reflective X-ray diffraction imaging (XRDI). For examples, the MDI film 120 of the multi-layered epitaxial stack 240 has a crystalline defect density in a range from about 0 pixels/cm² to about 10,000 pixels/cm², about 0 pixels/cm² to about 5,000 pixels/cm², about 0 pixels/cm² to about 1,000 pixels/cm², about 0 pixels/cm² to about 500 pixels/cm², about 0 pixels/cm² to about 400 pixels/cm², about 0 pixels/cm² to about 300 pixels/cm², about 0 pixels/cm² to about 200 pixels/cm², about 0 pixels/cm² to about 160 pixels/cm², about 0 pixels/cm² to about 158 pixels/cm², about 0 pixels/cm² to about 140 pixels/cm², about 0 pixels/cm² to about 120 pixels/cm², about 0 pixels/cm² to about 100 pixels/cm², about 0 pixels/cm² to about 80 pixels/cm², about 0 pixels/cm² to about 50 pixels/cm², about 10 pixels/cm² to about 500 pixels/cm², about 10 pixels/cm² to about 400 pixels/cm², about 10 pixels/cm² to about 300 pixels/cm², about 10 pixels/cm² to about 200 pixels/cm², about 10 pixels/cm² to about 160 pixels/cm², about 10 pixels/cm² to about 158 pixels/cm², about 10 pixels/cm² to about 140 pixels/cm², about 10 pixels/cm² to about 120 pixels/cm², about 10 pixels/cm² to about 100 pixels/cm², about 10 pixels/cm² to about 80 pixels/cm², about 50 pixels/cm² to about 500 pixels/cm², about 50 pixels/cm² to about 400 pixels/cm², about 50 pixels/cm² to about 300 pixels/cm², about 50 pixels/cm² to about 200 pixels/cm², about 50 pixels/cm² to about 160 pixels/cm², about 50 pixels/cm² to about 158 pixels/cm², about 50 pixels/cm² to about 140 pixels/cm², about 50 pixels/cm² to about 120 pixels/cm², about 50 pixels/cm² to about 100 pixels/cm², about 50 pixels/cm² to about 80 pixels/cm², about 50 pixels/cm² to about 50 pixels/cm², about 100 pixels/cm² to about 500 pixels/cm², about 100 pixels/cm² to about 400 pixels/cm², about 100 pixels/cm² to about 300 pixels/cm², about 100 pixels/cm² to about 200 pixels/cm², about 100 pixels/cm² to about 160 pixels/cm², about 100 pixels/cm² to about 158 pixels/cm², about 100 pixels/cm² to about 140 pixels/cm², or about 100 pixels/cm² to about 120 pixels/cm², as measured by reflective XRDI. In one or more examples, the MDI film 120 of the multi-layered epitaxial stack 240 has a crystalline defect density of less than 158 pixels/cm², as measured by reflective XRDI.

In one or more embodiments, a workpiece 200 is provided and contains a multi-layered epitaxial stack 240 containing an MDI film 120 disposed between a bottom FET module 110 and a top FET module 130. The bottom FET module 110 is disposed on the substrate 102 and contains a plurality of first silicon germanium layers 112 and silicon channel layers 114, where four of the first silicon germanium layers 112 are alternately stacked with three of the silicon channel layers 114. The top FET module 130 is disposed on the MDI film 120 and contains a plurality of the first silicon germanium layers 132 and the silicon channel layers 134, where three of the first silicon germanium layers 132 are alternately stacked with three of the silicon channel layers 134. The MDI film 120 contains a plurality of the first silicon germanium layers 126 and second silicon germanium layers 124, where three of the second silicon germanium layers 124 are alternately stacked with two of the first silicon germanium layers 126, and where the second silicon germanium layers 124 have a greater germanium concentration than the first silicon germanium layers 126. The MDI film 120 further contains a bottom silicon epi layer 122a and a top silicon epi layer 122b. The bottom silicon epi layer 122a is disposed between the bottom FET module 110 and the plurality of the first silicon germanium layers 126 and the second silicon germanium layers 124. The top silicon epi layer 122b is disposed between the top FET module 130 and the plurality of the first silicon germanium layers 126 and the second silicon germanium layers 124.

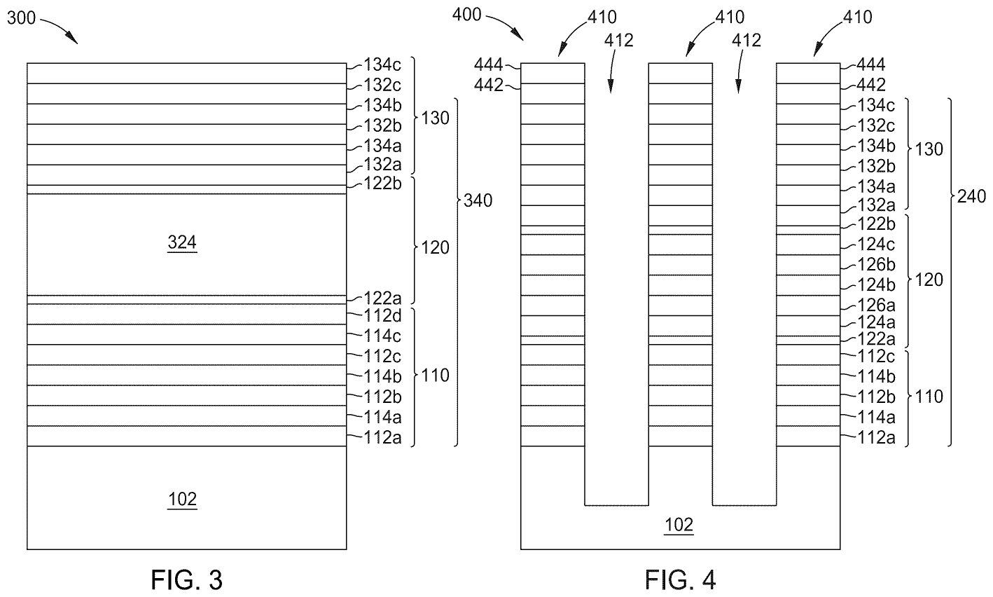

FIG. 3 depicts a multi-layered epitaxial stack 340, such as a cFET stack, according to one or more embodiments described and discussed herein. A workpiece 300 is provided and contains the multi-layered epitaxial stack 340 disposed on a substrate 102. An MDI film 120 is disposed between a bottom FET module 110 and a top FET module 130. In one or more embodiments, each of the bottom FET module 110 and the top FET module 130 may independently be or contain an MOS film. The multi-layered epitaxial stack 340 is a cFET which may be further processed to form a plurality of features, such as a plurality of cFET components separated by trenches, vias, spaces, or other gaps, as will be further discussed below.

In one or more embodiments, the multi-layered epitaxial stack 340 contains the same bottom FET module 110 and the same top FET module 130 as discussed and described for the multi-layered epitaxial stack 240. For example, the bottom FET module 110 contains four of the first silicon germanium layers 112 (e.g., 112a-112d) and three of the silicon channel layers 114 (e.g., 114a-114c) alternately stacked on each other. Also, the top FET module 130 contains three of the first silicon germanium layers 132 (e.g., 132a-132c) and three of the silicon channel layers 134 (e.g., 134a-134c) alternately stacked on each other. However, the MDI film 120 of the multi-layered epitaxial stack 340 contains a second silicon germanium layer 324, which is a single layer of silicon germanium, as opposed to a laminate stack, as in the MDI film 120 of the multi-layered epitaxial stacks 140, 240. The second silicon germanium layer 324 contains a germanium concentration of greater than the first silicon germanium layers 112, 132 (and the first silicon germanium layers 126, as described and discussed in other embodiments). The second silicon germanium layer 324 contains a germanium concentration of greater than 25 at %. The MDI film 120 further contains a bottom silicon epi layer 122a and a top silicon epi layer 122b separated by the second silicon germanium layer 324. The bottom silicon epi layer 122a is disposed between the bottom FET module 110 and the second silicon germanium layer 324. The top silicon epi layer 122b is disposed between the top FET module 130 and the second silicon germanium layer 324. The properties, compositions, layer thicknesses, and other attributes for the first silicon germanium layers 112, 126, 132, the silicon channel layers 114, 134, the bottom silicon epi layers 122a, and the top silicon epi layers 122b have been described and discussed above.

In one or more embodiments, the second silicon germanium layer 324 has a germanium concentration in a range from about or greater than 25 at %, about or greater than 28 at %, about or greater than 30 at %, about or greater than 32 at %, about or greater than 34 at %, about or greater than 35 at %, about or greater than 36 at %, about or greater than 38 at %, about or greater than 40 at %, about or greater than 42 at %, about or greater than 44 at %, about or greater than 45 at %, about or greater than 46 at %, about or greater than 46 at %, about or greater than 50 at %, about or greater than 52 at %, about or greater than 55 at %, or greater. For example, the second silicon germanium layer 324 has a germanium concentration in a range from about 25 at % to about 55 at %, about 30 at % to about 55 at %, about 30 at % to about 50 at %, about 30 at % to about 48 at %, about 30 at % to about 45 at %, about 30 at % to about 42 at %, about 30 at % to about 40 at %, about 30 at % to about 38 at %, about 30 at % to about 36 at %, about 30 at % to about 35 at %, about 30 at % to about 34 at %, about 30 at % to about 32 at %, about 32 at % to about 55 at %, about 32 at % to about 50 at %, about 32 at % to about 48 at %, about 32 at % to about 45 at %, about 32 at % to about 42 at %, about 32 at % to about 40 at %, about 32 at % to about 38 at %, about 32 at % to about 36 at %, about 32 at % to about 35 at %, about 32 at % to about 34 at %, about 34 at % to about 55 at %, about 34 at % to about 50 at %, about 34 at % to about 48 at %, about 34 at % to about 45 at %, about 34 at % to about 42 at %, about 34 at % to about 40 at %, about 34 at % to about 38 at %, about 34 at % to about 36 at %, about 34 at % to about 35 at %, about 38 at % to about 55 at %, about 38 at % to about 50 at %, about 38 at % to about 48 at %, about 38 at % to about 45 at %, about 38 at % to about 42 at %, about 38 at % to about 40 at %, about 40 at % to about 55 at %, about 40 at % to about 50 at %, about 40 at % to about 48 at %, about 40 at % to about 45 at %, or about 40 at % to about 42 at %.

In one or more embodiments, the second silicon germanium layer 324 has a silicon concentration in a range from about 50 at %, about 52 at %, about 54 at %, about 55 at %, about 56 at %, about 58 at %, about 60 at %, about 62 at %, about 64 at %, about 65 at %, about 66 at %, about 68 at %, about 70 at %, about 75 at %, or greater. For example, the second silicon germanium layer 324 has a silicon concentration in a range from about 50 at % to about 70 at %, about 50 at % to about 68 at %, about 50 at % to about 65 at %, about 50 at % to about 62 at %, about 50 at % to about 60 at %, about 50 at % to about 58 at %, about 50 at % to about 56 at %, about 50 at % to about 55 at %, about 50 at % to about 52 at %, about 52 at % to about 70 at %, about 52 at % to about 68 at %, about 52 at % to about 65 at %, about 52 at % to about 62 at %, about 52 at % to about 60 at %, about 52 at % to about 58 at %, about 52 at % to about 56 at %, about 52 at % to about 55 at %, about 54 at % to about 70 at %, about 54 at % to about 68 at %, about 54 at % to about 65 at %, about 54 at % to about 62 at %, about 54 at % to about 60 at %, about 54 at % to about 58 at %, about 54 at % to about 56 at %, about 54 at % to about 55 at %, about 56 at % to about 70 at %, about 56 at % to about 68 at %, about 56 at % to about 65 at %, about 56 at % to about 62 at %, about 56 at % to about 60 at %, about 58 at % to about 70 at %, about 58 at % to about 68 at %, about 58 at % to about 65 at %, about 58 at % to about 62 at %, or about 58 at % to about 60 at %.

In one or more embodiments, the second silicon germanium layer 324 has a carbon concentration in a range from about 0.1 at %, about 0.2 at %, about 0.3 at %, about 0.35 at % or about 0.4 at % to about 0.45 at %, about 0.5 at %, about 0.55 at %, about 0.6 at %, about 0.65 at %, about 0.7 at %, about 0.75 at %, about 0.8 at %, about 0.9 at %, about 1 at %, about 1.1 at %, about 1.2 at %, or greater. For example, the second silicon germanium layer 324 has a carbon concentration in a range from about 0.1 at % to about 1.2 at %, about 0.2 at % to about 1.2 at %, about 0.2 at % to about 1 at %, about 0.2 at % to about 0.8 at %, about 0.2 at % to about 0.7 at %, about 0.2 at % to about 0.6 at %, about 0.2 at % to about 0.5 at %, about 0.2 at % to about 0.4 at %, about 0.4 at % to about 1.2 at %, about 0.4 at % to about 1 at %, about 0.4 at % to about 0.8 at %, about 0.4 at % to about 0.7 at %, about 0.4 at % to about 0.6 at %, about 0.4 at % to about 0.5 at %, about 0.5 at % to about 1.2 at %, about 0.5 at % to about 1 at %, about 0.5 at % to about 0.8 at %, about 0.5 at % to about 0.7 at %, about 0.5 at % to about 0.6 at %, about 0.6 at % to about 1.2 at %, about 0.6 at % to about 1 at %, about 0.6 at % to about 0.8 at %, or about 0.6 at % to about 0.7 at %.

In one or more embodiments, the second silicon germanium layer 324 has a thickness in a range from a thickness in a range from about 20 nm, about 30 nm, about 35 nm, about 40 nm, about 45 nm, about 50 nm, about 55 nm, about 60 nm, about 65 nm, about 70 nm, about 75 nm, about 80 nm, about 90 nm, about 100 nm, or greater. For example, the second silicon germanium layer 324 has a thickness in a range from about 20 nm to about 100 nm, about 40 nm to about 100 nm, about 40 nm to about 90 nm, about 40 nm to about 80 nm, about 40 nm to about 70 nm, about 40 nm to about 65 nm, about 40 nm to about 60 nm, about 40 nm to about 55 nm, about 40 nm to about 50 nm, about 40 nm to about 45 nm, about 45 nm to about 100 nm, about 45 nm to about 90 nm, about 45 nm to about 80 nm, about 45 nm to about 70 nm, about 45 nm to about 65 nm, about 45 nm to about 60 nm, about 45 nm to about 55 nm, about 45 nm to about 50 nm, about 50 nm to about 100 nm, about 50 nm to about 90 nm, about 50 nm to about 80 nm, about 50 nm to about 70 nm, about 50 nm to about 65 nm, about 50 nm to about 60 nm, about 50 nm to about 55 nm, about 60 nm to about 100 nm, about 60 nm to about 90 nm, about 60 nm to about 80 nm, about 60 nm to about 70 nm, or about 60 nm to about 65 nm.

In one or more embodiments, the MDI film 120 of the multi-layered epitaxial stack 340 has a thickness in a range from about 20 nm, about 25 nm, about 30 nm, about 35 nm, about 40 nm, about 42 nm, or about 45 nm to about 48 nm, about 50 nm, about 52 nm, about 55 nm, about 60 nm, about 65 nm, about 70 nm, about 75 nm, about 80 nm, about 85 nm, about 90 nm, about 100 nm, or greater. For example, the MDI film 120 of the multi-layered epitaxial stack 340 has a thickness in a range from about 35 nm to about 65 nm, about 35 nm to about 60 nm, about 35 nm to about 55 nm, about 35 nm to about 50 nm, about 35 nm to about 48 nm, about 35 nm to about 45 nm, about 35 nm to about 40 nm, about 40 nm to about 65 nm, about 40 nm to about 60 nm, about 40 nm to about 55 nm, about 40 nm to about 50 nm, about 40 nm to about 48 nm, about 40 nm to about 45 nm, about 40 nm to about 42 nm, about 45 nm to about 65 nm, about 45 nm to about 60 nm, about 45 nm to about 55 nm, about 45 nm to about 50 nm, about 45 nm to about 48 nm, about 48 nm to about 65 nm, about 48 nm to about 60 nm, about 48 nm to about 55 nm, about 48 nm to about 50 nm, about 50 nm to about 65 nm, about 50 nm to about 60 nm, or about 50 nm to about 55 nm.

In one or more embodiments, the multi-layered epitaxial stack 340 has a thickness in a range from about 100 nm, about 120 nm, about 130 nm, about 140 nm, about 150 nm, about 160 nm, about 170 nm, about 180 nm, about 190 nm, about 200 nm, about 210 nm, about 220 nm, about 240 nm, about 250 nm, about 260 nm, about 280 nm, about 300 nm, or greater. For example, the multi-layered epitaxial stack 340 has a thickness in a range from about 100 nm to about 300 nm, about 130 nm to about 280 nm, about 130 nm to about 250 nm, about 130 nm to about 220 nm, about 130 nm to about 200 nm, about 130 nm to about 190 nm, about 130 nm to about 180 nm, about 130 nm to about 178 nm, about 130 nm to about 175 nm, about 130 nm to about 170 nm, about 130 nm to about 165 nm, about 130 nm to about 160 nm, about 130 nm to about 155 nm, about 130 nm to about 150 nm, about 130 nm to about 140 nm, about 150 nm to about 280 nm, about 150 nm to about 250 nm, about 150 nm to about 220 nm, about 150 nm to about 200 nm, about 150 nm to about 190 nm, about 150 nm to about 180 nm, about 150 nm to about 178 nm, about 150 nm to about 175 nm, about 150 nm to about 170 nm, about 150 nm to about 165 nm, about 150 nm to about 160 nm, about 150 nm to about 155 nm, about 160 nm to about 280 nm, about 160 nm to about 250 nm, about 160 nm to about 220 nm, about 160 nm to about 200 nm, about 160 nm to about 190 nm, about 160 nm to about 180 nm, about 160 nm to about 178 nm, about 160 nm to about 175 nm, about 160 nm to about 170 nm, or about 160 nm to about 165 nm.

In one or more embodiments, the MDI film 120 of the multi-layered epitaxial stack 340 has a crystalline defect density in a range from about 0 pixels/cm², about or less than 10 pixels/cm², about or less than 50 pixels/cm², about or less than 80 pixels/cm², about or less than 100 pixels/cm², about or less than 120 pixels/cm², or about or less than 150 pixels/cm² to about or less than 158 pixels/cm², about or less than 160 pixels/cm², about or less than 170 pixels/cm², about or less than 180 pixels/cm², about or less than 200 pixels/cm², about or less than 250 pixels/cm², about or less than 300 pixels/cm², about or less than 350 pixels/cm², about or less than 400 pixels/cm², about or less than 500 pixels/cm², about or less than 600 pixels/cm², about or less than 800 pixels/cm², about or less than 1,000 pixels/cm², about or less than 1,500 pixels/cm², about or less than 2,000 pixels/cm², about or less than 3,000 pixels/cm², about or less than 4,000 pixels/cm², about or less than 5,000 pixels/cm², about or less than 6,000 pixels/cm², about or less than 8,000 pixels/cm², or about or less than 10,000 pixels/cm², as measured by reflective X-ray diffraction imaging (XRDI). For examples, the MDI film 120 of the multi-layered epitaxial stack 340 has a crystalline defect density in a range from about 0 pixels/cm² to about 10,000 pixels/cm², about 0 pixels/cm² to about 5,000 pixels/cm², about 0 pixels/cm² to about 1,000 pixels/cm², about 0 pixels/cm² to about 500 pixels/cm², about 0 pixels/cm² to about 400 pixels/cm², about 0 pixels/cm² to about 300 pixels/cm², about 0 pixels/cm² to about 200 pixels/cm², about 0 pixels/cm² to about 160 pixels/cm², about 0 pixels/cm² to about 158 pixels/cm², about 0 pixels/cm² to about 140 pixels/cm², about 0 pixels/cm² to about 120 pixels/cm², about 0 pixels/cm² to about 100 pixels/cm², about 0 pixels/cm² to about 80 pixels/cm², about 0 pixels/cm² to about 50 pixels/cm², about 10 pixels/cm² to about 500 pixels/cm², about 10 pixels/cm² to about 400 pixels/cm², about 10 pixels/cm² to about 300 pixels/cm², about 10 pixels/cm² to about 200 pixels/cm², about 10 pixels/cm² to about 160 pixels/cm², about 10 pixels/cm² to about 158 pixels/cm², about 10 pixels/cm² to about 140 pixels/cm², about 10 pixels/cm² to about 120 pixels/cm², about 10 pixels/cm² to about 100 pixels/cm², about 10 pixels/cm² to about 80 pixels/cm², about 50 pixels/cm² to about 500 pixels/cm², about 50 pixels/cm² to about 400 pixels/cm², about 50 pixels/cm² to about 300 pixels/cm², about 50 pixels/cm² to about 200 pixels/cm², about 50 pixels/cm² to about 160 pixels/cm², about 50 pixels/cm² to about 158 pixels/cm², about 50 pixels/cm² to about 140 pixels/cm², about 50 pixels/cm² to about 120 pixels/cm², about 50 pixels/cm² to about 100 pixels/cm², about 50 pixels/cm² to about 80 pixels/cm², about 50 pixels/cm² to about 50 pixels/cm², about 100 pixels/cm² to about 500 pixels/cm², about 100 pixels/cm² to about 400 pixels/cm², about 100 pixels/cm² to about 300 pixels/cm², about 100 pixels/cm² to about 200 pixels/cm², about 100 pixels/cm² to about 160 pixels/cm², about 100 pixels/cm² to about 158 pixels/cm², about 100 pixels/cm² to about 140 pixels/cm², or about 100 pixels/cm² to about 120 pixels/cm², as measured by reflective XRDI. In one or more examples, the MDI film 120 of the multi-layered epitaxial stack 340 has a crystalline defect density of less than 158 pixels/cm², as measured by reflective XRDI.

In one or more embodiments, a workpiece 300 is provided and contains a multi-layered epitaxial stack 340 containing an MDI film 120 disposed between a bottom FET module 110 and a top FET module 130. The bottom FET module 110 is disposed on the substrate 102 and contains a plurality of first silicon germanium layers 112 and silicon channel layers 114, where four of the first silicon germanium layers 112 are alternately stacked with three of the silicon channel layers 114. The top FET module 130 is disposed on the MDI film 120 and contains a plurality of the first silicon germanium layers 132 and the silicon channel layers 134, where three of the first silicon germanium layers 132 are alternately stacked with three of the silicon channel layers 134. The MDI film 120 contains a second silicon germanium layer 324 which has a greater germanium concentration than the first silicon germanium layers 112, 132. For example, the second silicon germanium layer 324 contains a germanium concentration of greater than 25 at %, such as in a range from about 35 at % to about 45 at %. The MDI film 120 further contains a bottom silicon epi layer 122a and a top silicon epi layer 122b. The bottom silicon epi layer 122a is disposed between the bottom FET module 110 and the second silicon germanium layer 324. The top silicon epi layer 122b is disposed between the top FET module 130 and the second silicon germanium layer 324.

FIG. 4 depicts a workpiece 400 containing a plurality of features 410, such as cFETs, fabricated from a cFET stack, such as the multi-layered epitaxial stack 240 illustrated in FIG. 2, according to one or more embodiments described and discussed herein. In one or more embodiments, the workpiece 400 a plurality of features 410 separated by trenches 412 and disposed on a substrate 102. Each of the trenches 412 has relatively high aspect ratio, such as greater than 10. Each of the features 410 contains a multi-layered epitaxial stack 240 containing an MDI film 120 disposed between a bottom FET module 110 and a top FET module 130. Each of the features 410 also contains a pad oxide layer 442 (e.g., silicon oxide) disposed on the top FET module 130, and a nitride layer 444 (e.g., silicon nitride) disposed on the pad oxide layer 442.

For the workpiece 400, the bottom FET module 110 is disposed on the substrate 102 and contains a plurality of first silicon germanium layers 112 and silicon channel layers 114, where four of the first silicon germanium layers 112 are alternately stacked with three of the silicon channel layers 114. The top FET module 130 is disposed on the MDI film 120 and contains a plurality of the first silicon germanium layers 132 and the silicon channel layers 134, where three of the first silicon germanium layers 132 are alternately stacked with three of the silicon channel layers 134. The MDI film 120 contains a plurality of the first silicon germanium layers 126 and second silicon germanium layers 124, where three of the second silicon germanium layers 124 are alternately stacked with two of the first silicon germanium layers 126, and where the second silicon germanium layers 124 have a greater germanium concentration than the first silicon germanium layers 126. The MDI film 120 further contains a bottom silicon epi layer 122a and a top silicon epi layer 122b. The bottom silicon epi layer 122a is disposed between the bottom FET module 110 and the plurality of the first silicon germanium layers 126 and the second silicon germanium layers 124, as depicted in FIG. 4. The top silicon epi layer 122b is disposed between the top FET module 130 and the plurality of the first silicon germanium layers 126 and the second silicon germanium layers 124.

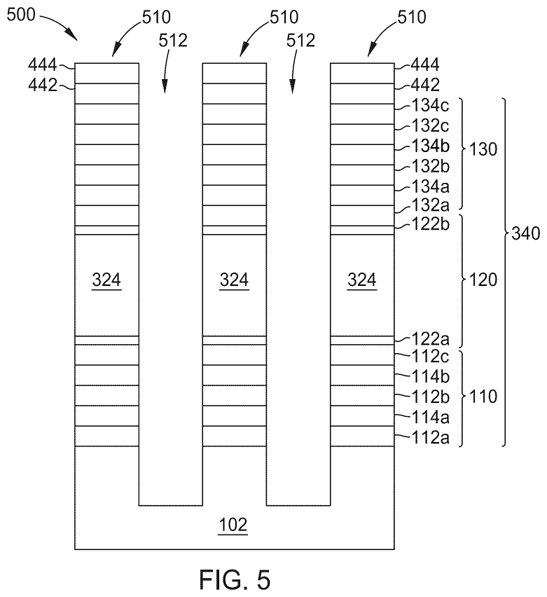

FIG. 5 depicts a workpiece 500 containing a plurality of features 510, such as cFETs, fabricated from a cFET stack, such as the multi-layered epitaxial stack 340 illustrated in FIG. 3, according to one or more embodiments described and discussed herein. In one or more embodiments, the workpiece 500 contains a plurality of features 510 separated by trenches 512 and disposed on a substrate 102. Each of the trenches 512 has relatively high aspect ratio, such as greater than 10. Also, each of the features 510 contains a multi-layered epitaxial stack 340 containing an MDI film 120 disposed between a bottom FET module 110 and a top FET module 130. Each of the features 510 also contains a pad oxide layer 442 (e.g., silicon oxide) disposed on the top FET module 130, and a nitride layer 444 (e.g., silicon nitride) disposed on the pad oxide layer 442.

For the workpiece 500, the bottom FET module 110 is disposed on the substrate 102 and contains a plurality of first silicon germanium layers 112 and silicon channel layers 114, where four of the first silicon germanium layers 112 are alternately stacked with three of the silicon channel layers 114. The top FET module 130 is disposed on the MDI film 120 and contains a plurality of the first silicon germanium layers 132 and the silicon channel layers 134, where three of the first silicon germanium layers 132 are alternately stacked with three of the silicon channel layers 134. The MDI film 120 contains a single second silicon germanium layer 324 disposed between a bottom silicon epi layer 122a and a top silicon epi layer 122b, as depicted in FIG. 5. The second silicon germanium layer 324 contains a concentration of germanium greater than the first silicon germanium layers 112, 132 and greater than 25 at %. The bottom silicon epi layer 122a is disposed between the bottom FET module 110 and the second silicon germanium layer 324. The top silicon epi layer 122b is disposed between the top FET module 130 and the second silicon germanium layer 324.

In one or more embodiments, each of the trenches 412, 512 has an aspect ratio of about or greater than 10, about or greater than 11, about or greater than 12, or about or greater than 13 to about or greater than 14, about or greater than 15, about or greater than 16, about or greater than 17, about or greater than 18, about or greater than 19, about or greater than 20, about or greater than 22, about or greater than 24, about or greater than 25, or greater. For example, each of the trenches 412, 512 has an aspect ratio of about or greater than 10 to about 25, about or greater than 12 to about 25, about or greater than 15 to about 25, about or greater than 18 to about 25, about or greater than 20 to about 25, about or greater than 22 to about 25, about 10 to about 25, about 10 to about 22, about 10 to about 20, about 10 to about 18, about 10 to about 16, about 10 to about 15, about 10 to about 14, about 10 to about 12, about 10 to about 11, about 12 to about 25, about 12 to about 22, about 12 to about 20, about 12 to about 18, about 12 to about 16, about 12 to about 15, about 12 to about 14, about 12 to about 13, about 14 to about 25, about 14 to about 22, about 14 to about 20, about 14 to about 18, about 14 to about 16, about 14 to about 15, about 15 to about 25, about 15 to about 22, about 15 to about 20, about 15 to about 18, about 15 to about 16, about 16 to about 25, about 16 to about 22, about 16 to about 20, about 16 to about 18, about 16 to about 17, about 18 to about 25, about 18 to about 22, about 18 to about 20, about 18 to about 19.

In one or more examples, each of the trenches 412, 512 has an aspect ratio of about or greater than 10 to about 25. In some examples, each of the trenches 412, 512 has an aspect ratio of about 12 to about 20. In other examples, each of the trenches 412, 512 has an aspect ratio of about 13 to about 18. In some examples, each of the trenches 412, 512 has an aspect ratio of about 14 to about 16.

In one or more embodiments, each of the trenches 412, 512 has an overall depth in a range from about 100 nm, about 150 nm, about 175 nm, about 180 nm, about 200 nm, about 235 nm, about 250 nm, about 270 nm, about 285 nm, about 300 nm, about 320 nm, about 350 nm, about 380 nm, about 400 nm, about 420 nm, about 450 nm, about 480 nm, about 500 nm, or greater. For example, each of the trenches 412, 512 has an overall depth in a range from about 100 nm to about 500 nm, about 200 nm to about 500 nm, about 200 nm to about 450 nm, about 200 nm to about 400 nm, about 200 nm to about 380 nm, about 200 nm to about 350 nm, about 200 nm to about 320 nm, about 200 nm to about 300 nm, about 200 nm to about 250 nm, about 250 nm to about 500 nm, about 250 nm to about 450 nm, about 250 nm to about 400 nm, about 250 nm to about 380 nm, about 250 nm to about 350 nm, about 250 nm to about 320 nm, about 250 nm to about 300 nm, about 250 nm to about 275 nm, about 300 nm to about 500 nm, about 300 nm to about 450 nm, about 300 nm to about 400 nm, about 300 nm to about 380 nm, about 300 nm to about 350 nm, about 300 nm to about 320 nm, about 300 nm to about 310 nm, about 350 nm to about 500 nm, about 350 nm to about 450 nm, about 350 nm to about 400 nm, about 350 nm to about 380 nm, about 350 nm to about 375 nm, or about 350 nm to about 360 nm.

In one or more embodiments, each of the trenches 412, 512 extends into the substrate 102 to a depth in a range from about 50 nm, about 80 nm, about 100 nm, about 120 nm, or about 150 nm to about 160 nm, about 165 nm, about 170 nm, about 172 nm, about 175 nm, about 180 nm, about 200 nm, about 220 nm, about 250 nm, or greater. For example, each of the trenches 412, 512 extends into the substrate 102 to a depth in a range from about 50 nm to about 250 nm, about 80 nm to about 250 nm, about 80 nm to about 200 nm, about 80 nm to about 190 nm, about 80 nm to about 180 nm, about 80 nm to about 175 nm, about 80 nm to about 170 nm, about 80 nm to about 160 nm, about 80 nm to about 150 nm, about 80 nm to about 120 nm, about 80 nm to about 100 nm, about 80 nm to about 90 nm, about 120 nm to about 250 nm, about 120 nm to about 200 nm, about 120 nm to about 190 nm, about 120 nm to about 180 nm, about 120 nm to about 175 nm, about 120 nm to about 170 nm, about 120 nm to about 160 nm, about 120 nm to about 150 nm, about 120 nm to about 130 nm, about 150 nm to about 250 nm, about 150 nm to about 200 nm, about 150 nm to about 190 nm, about 150 nm to about 180 nm, about 150 nm to about 175 nm, about 150 nm to about 170 nm, or about 150 nm to about 160 nm.

In some embodiments, each of the features 410, 510 further contains the pad oxide layer 442 and/or the nitride layer 444 disposed on the multi-layered epitaxial stack 240, 340, as depicted in FIGS. 4 and 5. The pad oxide layer 442 may be disposed on the top FET module 130. The pad oxide layer 442 contains one or more oxides, such as silicon oxide, and may be deposited by a chemical vapor deposition (CVD) process, an atomic layer deposition (ALD) process, and/or a thermal oxidation process. The pad oxide layer 442 has a thickness in a range from about 0.5 nm to about 5 nm, such as about 0.8 nm to about 4 nm, about 1 nm to about 3 nm, about 1.5 nm to about 2.5 nm, about 1.6 nm to about 2.4 nm, about 1.8 nm to about 2.2 nm, or about 2 nm.

The nitride layer 444 may be disposed on pad oxide layer 442. The nitride layer 444 contains one or more nitrides, such as silicon nitride, and may be deposited by a CVD process, an ALD process, and/or a thermal nitridation process. The nitride layer 444 has a thickness in a range from about 10 nm to about 50 nm, about 20 nm to about 40 nm, about 25 nm to about 35 nm, about 28 nm to about 32 nm, or about 30 nm.

In one or more embodiments, the workpiece 400 containing a plurality of features 410, as depicted in FIG. 4, may be fabricated by one or more processes. For example, a method for fabricating a device, such as the workpiece 400 containing a plurality of features 410, includes depositing a bottom FET module 110 on a substrate 102, depositing an MDI film 120 on the bottom FET module 110, and depositing a top FET module 130 on the MDI film 120. The bottom FET module 110 contains a plurality of first silicon germanium layers 112, 132 and silicon channel layers 114, 134. The first silicon germanium layers 112, 132 and the silicon channel layers 114, 134 are alternately stacked on each other. The top FET module 130 contains a plurality of the first silicon germanium layers 112, 132 and the silicon channel layers 114, 134. The first silicon germanium layers 112, 132 and the silicon channel layers 114, 134 are alternately stacked on each other. The MDI film 120 contains a bottom silicon epi layer 122a and a top silicon epi layer 122b separated by a plurality of the first silicon germanium layers 112, 132 and second silicon germanium layers 124. The first silicon germanium layers 112, 132 the second silicon germanium layers 124 are alternately stacked on each other, and where the second silicon germanium layers 124 have a greater germanium concentration than the first silicon germanium layers 112, 132. The bottom silicon epi layer 122a is disposed between the bottom FET module 110 and the plurality of the first silicon germanium layers 126 and the second silicon germanium layers 124. The top silicon epi layer 122b is disposed between the top FET module 130 and the plurality of the first silicon germanium layers 126 and the second silicon germanium layers 124. The method also includes depositing a pad oxide layer 442 containing silicon oxide on the top FET module 130 and depositing a nitride layer 444 containing silicon nitride on the pad oxide layer 442. The method further includes forming a plurality of features 410, 510 separated by trenches 412, 512 and disposed on the substrate 102 by etching the trenches 412, 512 through at least the nitride layer, the pad oxide layer 442, the top FET module 130, the MDI film 120, and the bottom FET module 110 during an etching process, each of the trenches 412, 512 has an aspect ratio of greater than 10, and each of the features 410, 510 contains a multi-layered epitaxial stack 140 containing the MDI film 120 disposed between the FET module and the top FET module 130, the pad oxide layer 442 disposed on the top FET module 130, and the nitride layer 444 disposed on the pad oxide layer 442.

In one or more embodiments, the workpiece 500 containing a plurality of features 510, as depicted in FIG. 5, may be fabricated by one or more processes. For example, a method for fabricating a device, such as the workpiece 500 containing a plurality of features 510, includes depositing a bottom FET module 110 on a substrate 102, depositing an MDI film 120 on the bottom FET module 110, and depositing a top FET module 130 on the MDI film 120. The bottom FET module 110 contains a plurality of first silicon germanium layers 112, 132 and silicon channel layers 114, 134. The first silicon germanium layers 112, 132 and the silicon channel layers 114, 134 are alternately stacked on each other. The top FET module 130 contains a plurality of the first silicon germanium layers 112, 132 and the silicon channel layers 114, 134. The first silicon germanium layers 112, 132 and the silicon channel layers 114, 134 are alternately stacked on each other. The MDI film 120 contains a second silicon germanium layer disposed between a bottom silicon epi layer 122a and a top silicon epi layer 122b. The second silicon germanium layer contains a concentration of germanium greater than the first silicon germanium layers 112, 132 and greater than 25 at %. The bottom silicon epi layer 122a is disposed between the bottom FET module 110 and the second silicon germanium layer 324. The top silicon epi layer 122b is disposed between the top FET module 130 and the second silicon germanium layer 324. The method also includes depositing a pad oxide layer 442 containing silicon oxide on the top FET module 130 and depositing a nitride layer 444 containing silicon nitride on the pad oxide layer 442. The method further includes forming a plurality of features 410, 510 separated by trenches 412, 512 and disposed on the substrate 102 by etching the trenches 412, 512 through at least the nitride layer, the pad oxide layer 442, the top FET module 130, the MDI film 120, and the bottom FET module 110 during an etching process. Each of the trenches 412, 512 has an aspect ratio of greater than 10. Each of the features 410, 510 contains a multi-layered epitaxial stack 140 containing the MDI film 120 disposed between the FET module and the top FET module 130, the pad oxide layer 442 disposed on the top FET module 130, and the nitride layer 444 disposed on the pad oxide layer 442.

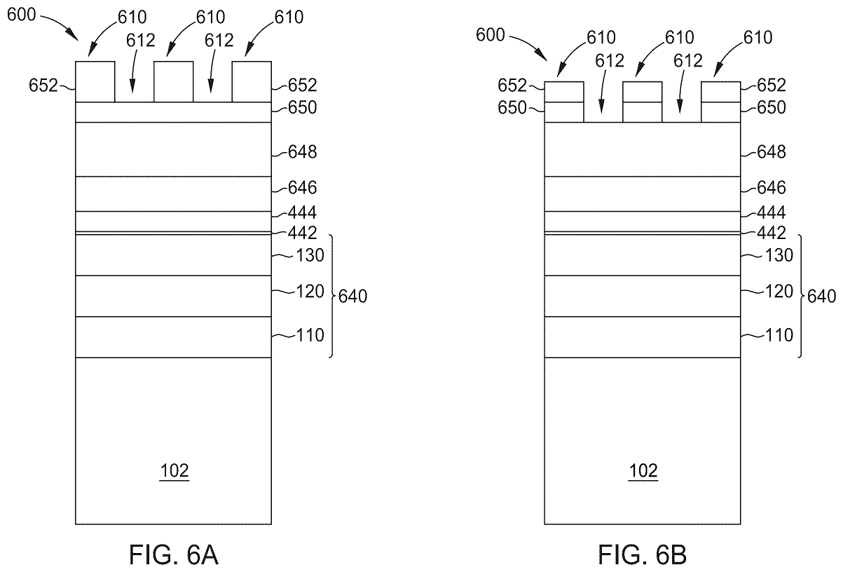

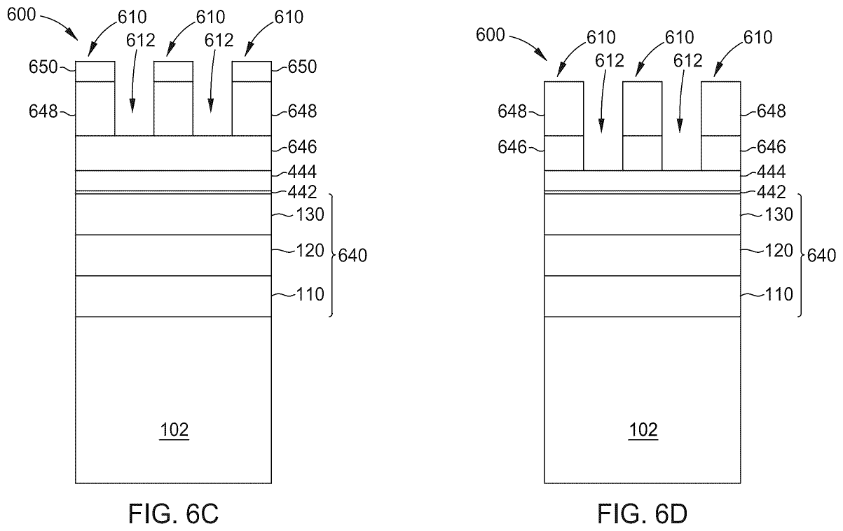

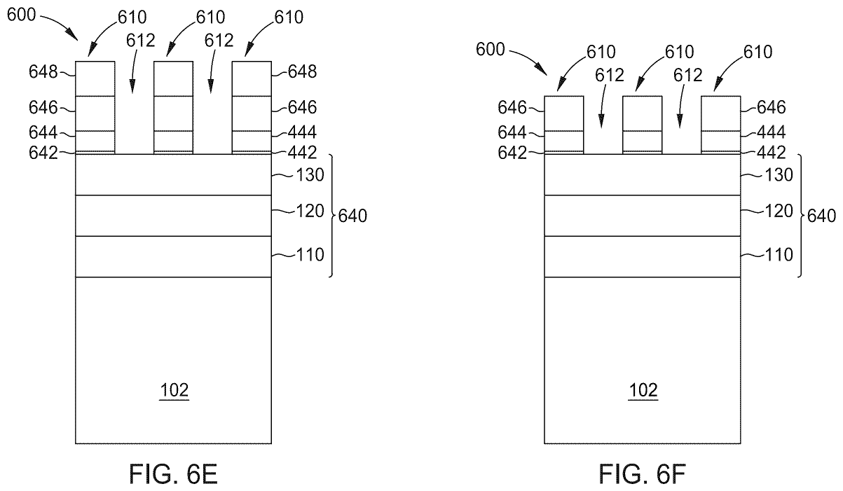

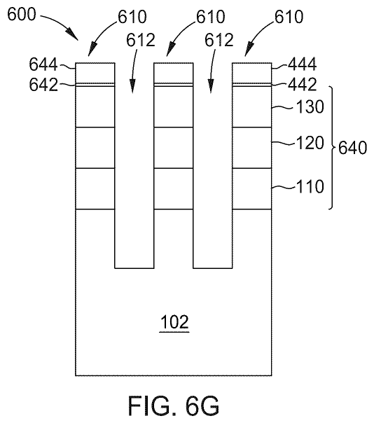

FIGS. 6A-6G depict a workpiece 600 at different intervals of fabricating a plurality of features 610, such as cFETs, according to one or more embodiments described and discussed herein. The plurality of features 610 may be fabricated from a cFET stack, such as any multi-layered epitaxial stack including the multi-layered epitaxial stack 140, 240, 340 illustrated in FIGS. 1-3. The plurality of features 610 may be or include any plurality of features including the plurality of features 410, 510, as described and discussed herein. A plurality of trenches 612 may be used to form boundaries of the plurality of features 610. Similarly, the plurality of trenches 612 may be or include any plurality of trenches (e.g., vias, spaces, or other gaps) including the plurality of trenches 412, 512, as described and discussed herein.

FIG. 6A depicts the workpiece 600 containing a multi-layered epitaxial stack 640 containing an MDI film 120 disposed between a bottom FET module 110 and a top FET module 130. The multi-layered epitaxial stack 640 may be any multi-layered epitaxial stack including the multi-layered epitaxial stack 140, 240, 340, described and discussed herein. The workpiece 600 contains a pad oxide layer 442 disposed on the top FET module 130, and the nitride layer 444 disposed on the pad oxide layer 442, as described and discussed herein.

In addition, the workpiece 600 contains an oxide layer 646 (e.g., high temperature oxide, HTO) disposed on the nitride layer 444, an amorphous carbon layer 648 (e.g., Advanced Patterning Film (APF), commercially available from Applied Materials, Inc.) disposed on the oxide layer 646, an anti-reflective coating (ARC) layer 650 disposed on the amorphous carbon layer 648, and a photoresist (PR) layer 652 disposed on the ARC layer 650. The oxide layer 646 may be deposited by CVD and may have a thickness in a range from about 50 nm to 100 nm, such as about 70 nm. The amorphous carbon layer 648 may be deposited by CVD and may have a thickness in a range from about 50 nm to 100 nm, such as about 66 nm. The ARC layer 650 may be deposited by CVD and may have a thickness in a range from about 10 nm to 50 nm, such as about 22 nm. The PR layer 652 may be deposited by spin-coating or CVD and may have a thickness in a range from about 25 nm to 80 nm, such as about 50 nm. As depicted in FIG. 6A, the PR layer 652 has been exposed and developed and contains the pattern of the features and trenches, such as the features 610 and the trenches 612 during the etching processes.

FIG. 6B depicts the workpiece 600 after being exposed to an SiARC etch process to extend the trenches 612 through the ARC layer 650, according to one or more embodiments described and discussed herein. FIG. 6C depicts the workpiece 600 after being exposed to an APF etch process to extend the trenches 612 through the amorphous carbon layer 648, according to one or more embodiments described and discussed herein. FIG. 6D depicts the workpiece 600 after being exposed to an HTO etch process to extend the trenches 612 through the oxide layer 646, according to one or more embodiments described and discussed herein. FIG. 6E depicts the workpiece 600 after being exposed to a nitride-oxide etch process to extend the trenches 612 through the nitride layer 444 and the pad oxide layer 442, according to one or more embodiments described and discussed herein. FIG. 6F depicts the workpiece 600 after being exposed to an APF strip etch process to remove the remaining portions of the amorphous carbon layer 648, according to one or more embodiments described and discussed herein.

FIG. 6G depicts the workpiece 600 after being exposed to a cyclic etch process to extend the multi-layered epitaxial stack 640 and partially into the substrate 101, according to one or more embodiments described and discussed herein.

In one or more embodiments, the cyclic etch process includes a first sub-cycle step containing exposing the workpiece to an oxygen plasma during a main etch. The oxygen plasma contains an etch gas containing oxygen (O₂), hydrogen bromide (HBr), and chlorine (Cl₂). The cyclic etch process also includes a second sub-cycle step containing exposing the workpiece to a passivation gas containing oxygen during a passivation step. The cyclic etch process also includes a third sub-cycle step containing exposing the workpiece to a fluoride reagent containing nitrogen fluoride (NF₃), carbon tetrafluoride (CF₄), oxygen (O₂) during a removal step to etch the horizontal sections of the passivation layer. For example, the horizontal surfaces of the passivation layer are exposed on to a fluoride reagent to selectively remove the passivation layer from the horizontal surfaces of the features while maintaining the passivation layer on the vertical surfaces of the features. The first, second, and third sub-cycle steps may independently be repeated 2, 3, 4, 5, 6, 7, 8, 9, 10, or more times to obtain the desired etch depth of the trenches.

In other embodiments, the cyclic etch process includes a first sub-cycle step containing exposing the workpiece to an oxygen plasma at a first bias power during a main etch. The oxygen plasma contains an etch gas containing oxygen (O₂), hydrogen bromide (HBr), and chlorine (Cl₂). The cyclic etch process also includes a second sub-cycle step containing exposing the workpiece to the oxygen plasma at a second bias power during the main etch. The first bias power of the plasma is greater than the second bias power. In one or more examples, the first bias power is in a range from about 2 kW to about 6 kW and the second bias power is in a range from about 1 kW to about 3 kW. The first and second sub-cycle steps may independently be repeated 2, 3, 4, 5, 6, 7, 8, 9, 10, or more times to obtain the desired etch depth of the trenches. In some examples, the second sub-cycle step is repeated 3, 4, 5, 6, 7, 8, or 9 times for every one of the first sub-cycle step.

In one or more embodiments, prior to the etching process, the method also includes depositing the oxide layer 646 (HTO) on the nitride layer 444, depositing the amorphous carbon layer 648 (APF) on the oxide layer 646, depositing the anti-reflective coating (ARC) layer 650 on the amorphous carbon layer 648, and depositing the photoresist (PR) layer 652 on the ARC layer. The method further includes pattering and developing the photoresist layer 652 to form a pattern of the features 610 and/or the trenches 612 during the etching process.

In some embodiments, the etching process includes repeating a cyclic etch process to form the trenches 612, where the cyclic etch process includes exposing horizontal surfaces above the workpiece 600 to a main etch containing an oxygen plasma, then depositing a passivation layer on horizontal and vertical surfaces, then exposing the passivation layer on the horizontal surfaces to a fluoride reagent to selectively remove the passivation layer from the horizontal surfaces while maintaining the passivation layer on the vertical surfaces.

Most traditional epitaxial deposition chambers, chemical vapor deposition (CVD) chambers or atomic layer deposition (ALD) chambers may be used as the processing chamber suitable for performing the epitaxy and or other vapor deposition processes described and discussed herein. An example of a tool or system that may benefit from the epi and/or vapor deposition processes described and discussed herein is the Centura® system or Endura® system with Centura® Epi 300 Reduced Pressure (RP) Epi CVD chamber, commercially available from Applied Materials, Inc. Another example of a tool or system that may benefit from the epi and/or vapor deposition processes described and discussed herein is the Centura® system or Endura® system with an iSprint™ ALD/CVD SSW chamber, commercially available from Applied Materials, Inc.

The present disclosure provides, among others, the following embodiments, each of which may be considered as optionally including any alternate embodiments per one or more of the following Clauses contained in Clause Groups 1-3. Any one or more Clauses within Clause Group 1, 2, or 3 may be combined with any one or more Clauses within any one or more of Clause Group 1, 2, or 3. The Clause Groups 1-3 are as follows:

### Clause Group 1

Clause 1. A workpiece, comprising: a multi-layered epitaxial stack disposed on a substrate, wherein the multi-layered epitaxial stack comprises a middle dielectric isolation (MDI) film disposed between a bottom field effect transistor (FET) module and a top FET module, wherein: the bottom FET module is disposed on the substrate; the bottom FET module comprises a plurality of first silicon germanium layers and silicon channel layers, wherein the first silicon germanium layers and the silicon channel layers are alternately stacked on each other; the top FET module is disposed on the MDI film; the top FET module comprises a plurality of the first silicon germanium layers and the silicon channel layers, wherein the first silicon germanium layers and the silicon channel layers are alternately stacked on each other; and the MDI film comprises: a plurality of the first silicon germanium layers and second silicon germanium layers, wherein the first silicon germanium layers the second silicon germanium layers are alternately stacked on each other, and wherein the second silicon germanium layers have a greater germanium concentration than the first silicon germanium layers; a bottom silicon epi layer disposed between the bottom FET module and the plurality of the first silicon germanium layers and the second silicon germanium layers; and a top silicon epi layer disposed between the top FET module and the plurality of the first silicon germanium layers and the second silicon germanium layers.

Clause 2. A workpiece, comprising: a multi-layered epitaxial stack disposed on a substrate, wherein the multi-layered epitaxial stack comprises a middle dielectric isolation (MDI) film disposed between a bottom field effect transistor (FET) module and a top FET module, wherein: the bottom FET module is disposed on the substrate; the bottom FET module comprises a plurality of first silicon germanium layers and silicon channel layers, wherein three of the first silicon germanium layers are alternately stacked with two of the silicon channel layers; the top FET module is disposed on the MDI film; the top FET module comprises a plurality of the first silicon germanium layers and the silicon channel layers, wherein two of the first silicon germanium layers are alternately stacked with two of the silicon channel layers; the MDI film comprises a plurality of the first silicon germanium layers and second silicon germanium layers, wherein three of the second silicon germanium layers are alternately stacked with two of the first silicon germanium layers, and wherein the second silicon germanium layers have a greater germanium concentration than the first silicon germanium layers; and the MDI film further comprises a bottom silicon epi layer disposed between the bottom FET module and the plurality of the first silicon germanium layers and the second silicon germanium layers and a top silicon epi layer disposed between the top FET module and the plurality of the first silicon germanium layers and the second silicon germanium layers.

Clause 3. A method of fabricating a film stack, comprising: depositing a bottom field effect transistor (FET) module on a substrate at a first temperature in a range from about 575° C. to about 625° C.; depositing a middle dielectric isolation (MDI) film on the bottom FET module at a second temperature in a range from about 575° C. to about 625° C.; and depositing a top FET module on the MDI film at a third temperature in a range from about 575° C. to about 625° C.; wherein the bottom FET module comprises a plurality of first silicon germanium layers and silicon channel layers, wherein the first silicon germanium layers and the silicon channel layers are alternately stacked on each other; the top FET module comprises a plurality of the first silicon germanium layers and the silicon channel layers, wherein the first silicon germanium layers and the silicon channel layers are alternately stacked on each other; and the MDI film comprises: a plurality of the first silicon germanium layers and second silicon germanium layers, wherein the first silicon germanium layers the second silicon germanium layers are alternately stacked on each other, and wherein the second silicon germanium layers have a greater germanium concentration than the first silicon germanium layers; a bottom silicon epi layer disposed between the bottom FET module and the plurality of the first silicon germanium layers and the second silicon germanium layers; and a top silicon epi layer disposed between the top FET module and the plurality of the first silicon germanium layers and the second silicon germanium layers.

Clause 4. The workpiece and/or the method according to any one of Clauses 1-3, wherein the plurality of first silicon germanium layers and silicon channel layers of the bottom FET module comprises three of the first silicon germanium layers and two of the silicon channel layers alternately stacked on each other.

Clause 5. The workpiece and/or the method according to any one of Clauses 1-4, wherein the plurality of first silicon germanium layers and silicon channel layers of the top FET module comprises two of the first silicon germanium layers and two of the silicon channel layers alternately stacked on each other.

Clause 6. The workpiece and/or the method according to any one of Clauses 1-5, wherein the plurality of the first silicon germanium layers and second silicon germanium layers of the MDI film comprises three of the second silicon germanium layers and two of the first silicon germanium layers alternately stacked on each other.

Clause 7. The workpiece and/or the method according to any one of Clauses 1-6, wherein each of the first silicon germanium layers independently has a germanium concentration in a range from about 10 at % to about 20 at %, such as about 12 at % to about 18 at %, about 14 at % to about 16 at %, such as 15 at %.

Clause 8. The workpiece and/or the method according to any one of Clauses 1-7, wherein each of the first silicon germanium layers independently has a silicon concentration in a range from about 80 at % to about 90 at %, such as about 82 at % to about 88 at %, about 84 at % to about 86 at %, such as 85 at %.

Clause 9. The workpiece and/or the method according to any one of Clauses 1-8, wherein each of the first silicon germanium layers independently has a carbon concentration in a range from about 0.2 at % to about 1 at %, such as about 0.3 at % to about 0.8 at %, about 0.4 at % to about 0.6 at %, such as 0.5 at %.

Clause 10. The workpiece and/or the method according to any one of Clauses 1-9, wherein each of the first silicon germanium layers independently has a thickness in a range from about 5 nm to about 15 nm, such as about 6 nm to about 14 nm, about 8 nm to about 12 nm, or about 10 nm.

Clause 11. The workpiece and/or the method according to any one of Clauses 1-10, wherein each of the second silicon germanium layers independently has a germanium concentration in a range from about 30 at % to about 50 at %, such as about 32 at % to about 48 at %, about 34 at % to about 46 at %, about 38 at % to about 42 at %, such as 40 at %.

Clause 12. The workpiece and/or the method according to any one of Clauses 1-11, wherein each of the second silicon germanium layers independently has a silicon concentration in a range from about 50 at % to about 70 at %, such as about 52 at % to about 68 at %, about 54 at % to about 66 at %, about 58 at % to about 62 at %, such as 60 at %.

Clause 13. The workpiece and/or the method according to any one of Clauses 1-12, wherein each of the second silicon germanium layers independently has a carbon concentration in a range from about 0.2 at % to about 1 at %, such as about 0.3 at % to about 0.8 at %, about 0.4 at % to about 0.6 at %, such as 0.5 at %.

Clause 14. The workpiece and/or the method according to any one of Clauses 1-13, wherein each of the second silicon germanium layers independently has a thickness in a range from about 4 nm to about 12 nm, such as about 6 nm to about 10 nm, about 7 nm to about 9 nm, or about 8 nm.

Clause 15. The workpiece and/or the method according to any one of Clauses 1-14, wherein each of the silicon channel layers independently has a silicon concentration of greater than 95 at % to 100 at %, such as about 98 at % to 100 at %, about 99 at % to 100 at %, or about 99.5 at % to 100 at %.

Clause 16. The workpiece and/or the method according to any one of Clauses 1-15, wherein each of the silicon channel layers independently has a thickness in a range from about 5 nm to about 15 nm, such as about 6 nm to about 14 nm, about 8 nm to about 12 nm, or about 10 nm.

Clause 17. The workpiece and/or the method according to any one of Clauses 1-16, wherein each of the bottom silicon epi layers and the top silicon epi layers independently has a silicon concentration of greater than 95 at % to 100 at %, such as about 98 at % to 100 at %, about 99 at % to 100 at %, or about 99.5 at % to 100 at %.

Clause 18. The workpiece and/or the method according to any one of Clauses 1-17, wherein each of the bottom silicon epi layers and the top silicon epi layers independently has a thickness in a range from about 0.5 nm to about 4 nm, such as about 1 nm to about 3 nm, about 1.5 nm to about 2.5 nm, or about 2 nm.

Clause 19. The workpiece and/or the method according to any one of Clauses 1-18, wherein each of the bottom and top FET modules independently has a thickness in a range from about 20 nm to about 70 nm, such as about 40 nm to about 50 nm.

Clause 20. The workpiece and/or the method according to any one of Clauses 1-19, wherein the bottom FET module has a thickness in a range from about 40 nm to about 60 nm, and the top FET module has a thickness in a range from about 30 nm to about 50 nm.

Clause 21. The workpiece and/or the method according to any one of Clauses 1-20, wherein the MDI film has a thickness in a range from about 35 nm to about 65 nm, such as about 40 nm to about 55 nm, about 45 nm to about 50 nm, or about 48 nm.

Clause 22. The workpiece and/or the method according to any one of Clauses 1-21, wherein the multi-layered epitaxial stack has a thickness in a range from about 100 nm to about 180 nm, such as about 120 nm to about 160 nm, or about 138 nm.

Clause 23. The workpiece and/or the method according to any one of Clauses 1-22, wherein the multi-layered epitaxial stack is a complementary field-effect transistor (cFET).

Clause 24. The workpiece and/or the method according to any one of Clauses 1-23, wherein each of the bottom FET module and the top FET module independently comprises a metal oxide semiconductor (MOS) film.

Clause 25. The workpiece and/or the method according to any one of Clauses 1-24, wherein the multi-layered epitaxial stack has a wafer bow in a range from about 40 μm to about 70 μm, such as about 50 μm to about 60 μm, such as about 55 μm.

Clause 26. The workpiece and/or the method according to any one of Clauses 1-25, wherein a top interface of the bottom FET module comprises the first silicon germanium layer having an abruptness value in a range from about 1.1 nm to about 1.4 nm, such as about 1.15 nm to about 1.3 nm, about 1.18 nm to about 1.25 nm, or about 1.21 nm.

Clause 27. The workpiece and/or the method according to any one of Clauses 1-26, wherein a bottom interface of the bottom FET module comprises the first silicon germanium layer having an abruptness value in a range from about 1.0 nm to about 1.3 nm, such as about 1.05 nm to about 1.25 nm, about 1.08 nm to about 1.15 nm, or about 1.1 nm.

Clause 28. The workpiece and/or the method according to any one of Clauses 1-27, wherein a bottom interface of the top FET module comprises the silicon channel layer having an abruptness value in a range from about 1.0 nm to about 1.3 nm, such as about 1.05 nm to about 1.25 nm, about 1.1 nm to about 1.2 nm, or about 1.11 nm.

Clause 29. The workpiece and/or the method according to any one of Clauses 1-28, wherein a top interface of the top FET module comprises the second silicon germanium layer having an abruptness value in a range from about 1.0 nm to about 1.3 nm, such as about 1.05 nm to about 1.25 nm, about 1.1 nm to about 1.2 nm, or about 1.14 nm.

Clause 30. The workpiece and/or the method according to any one of Clauses 1-29, wherein each of the first, second, and third temperatures is independently in a range from about 590° C. to about 610° C.

Clause 31. The workpiece and/or the method according to any one of Clauses 1-30, wherein each of the first silicon germanium layers and each the second silicon germanium layers independently contain carbon.

Clause 32. The workpiece and/or the method according to any one of Clauses 1-31, wherein each of the first silicon germanium layers and each the second silicon germanium layers are independently deposited from a deposition gas by an epitaxial process, and wherein the deposition gas comprises hydrogen (H₂), a silicon precursor, a silicon chlorine precursor, a silicon carbon precursor, and a germanium precursor.

Clause 33. The workpiece and/or the method according to any one of Clauses 1-32, wherein each of the first silicon germanium layers and each the second silicon germanium layers are independently deposited from a deposition gas by an epitaxial process, and wherein the deposition gas comprises hydrogen (H₂), silane, dichlorosilane, germane, and monomethyl silane.

Clause 34. The workpiece and/or the method according to any one of Clauses 1-33, wherein each of the silicon channel layers is independently deposited from a deposition gas by an epitaxial process, and wherein the deposition gas comprises hydrogen (H₂) and silane.

Clause 35. The workpiece and/or the method according to any one of Clauses 1-34, wherein each of the bottom silicon epi layers and each the top silicon epi layer are independently deposited from a deposition gas by an epitaxial process, and wherein the deposition gas comprises hydrogen (H₂) and silane.

### Clause Group 2

Clause 1. A workpiece, comprising: a plurality of features separated by trenches and disposed on a substrate, wherein each of the trenches has an aspect ratio of greater than 10, and wherein each of the features comprises a multi-layered epitaxial stack comprising a middle dielectric isolation (MDI) film disposed between a bottom field effect transistor (FET) module and a top FET module, wherein: the bottom FET module is disposed on the substrate; the bottom FET module comprises a plurality of first silicon germanium layers and silicon channel layers, wherein the first silicon germanium layers and the silicon channel layers are alternately stacked on each other; the top FET module is disposed on the MDI film; the top FET module comprises a plurality of the first silicon germanium layers and the silicon channel layers, wherein the first silicon germanium layers and the silicon channel layers are alternately stacked on each other; and the MDI film comprises: a plurality of the first silicon germanium layers and second silicon germanium layers, wherein the first silicon germanium layers the second silicon germanium layers are alternately stacked on each other, and wherein the second silicon germanium layers have a greater germanium concentration than the first silicon germanium layers; a bottom silicon epi layer disposed between the bottom FET module and the plurality of the first silicon germanium layers and the second silicon germanium layers; and a top silicon epi layer disposed between the top FET module and the plurality of the first silicon germanium layers and the second silicon germanium layers.

Clause 2. A workpiece, comprising: a plurality of features separated by trenches and disposed on a substrate, wherein each of the trenches has an aspect ratio of greater than 10, and wherein each of the features comprises a multi-layered epitaxial stack comprising a middle dielectric isolation (MDI) film disposed between a bottom field effect transistor (FET) module and a top FET module, wherein: the bottom FET module is disposed on the substrate; the bottom FET module comprises a plurality of first silicon germanium layers and silicon channel layers, wherein four of the first silicon germanium layers are alternately stacked with three of the silicon channel layers; the top FET module is disposed on the MDI film; the top FET module comprises a plurality of the first silicon germanium layers and the silicon channel layers, wherein three of the first silicon germanium layers are alternately stacked with three of the silicon channel layers; the MDI film comprises a plurality of the first silicon germanium layers and second silicon germanium layers, wherein three of the second silicon germanium layers are alternately stacked with two of the first silicon germanium layers, and wherein the second silicon germanium layers have a greater germanium concentration than the first silicon germanium layers; and the MDI film further comprises a bottom silicon epi layer disposed between the bottom FET module and the plurality of the first silicon germanium layers and the second silicon germanium layers and a top silicon epi layer disposed between the top FET module and the plurality of the first silicon germanium layers and the second silicon germanium layers.

Clause 3. A method of fabricating a device, comprising: depositing a bottom field effect transistor (FET) module on a substrate; depositing a middle dielectric isolation (MDI) film on the bottom FET module; depositing a top FET module on the MDI film; wherein the bottom FET module comprises a plurality of first silicon germanium layers and silicon channel layers, wherein the first silicon germanium layers and the silicon channel layers are alternately stacked on each other; the top FET module comprises a plurality of the first silicon germanium layers and the silicon channel layers, wherein the first silicon germanium layers and the silicon channel layers are alternately stacked on each other; and the MDI film comprises: a plurality of the first silicon germanium layers and second silicon germanium layers, wherein the first silicon germanium layers the second silicon germanium layers are alternately stacked on each other, and wherein the second silicon germanium layers have a greater germanium concentration than the first silicon germanium layers; a bottom silicon epi layer disposed between the bottom FET module and the plurality of the first silicon germanium layers and the second silicon germanium layers; and a top silicon epi layer disposed between the top FET module and the plurality of the first silicon germanium layers and the second silicon germanium layers; depositing a pad oxide layer comprising silicon oxide on the top FET module; depositing a nitride layer comprising silicon nitride on the pad oxide layer; and forming a plurality of features separated by trenches and disposed on the substrate by etching the trenches through at least the nitride layer, the pad oxide layer, the top FET module, the MDI film, and the bottom FET module during an etching process, wherein each of the trenches has an aspect ratio of greater than 10, and wherein each of the features comprises a multi-layered epitaxial stack comprising the MDI film disposed between the FET module and the top FET module, the pad oxide layer disposed on the top FET module, and the nitride layer disposed on the pad oxide layer.

Clause 4. The workpiece and/or the method according to any one of Clauses 1-3, wherein each of the trenches has an aspect ratio in a range from about 12 to about 20, such as about 14 to about 16.

Clause 5. The workpiece and/or the method according to any one of Clauses 1-4, wherein each of the features further comprises: a pad oxide layer comprising silicon oxide disposed on the multi-layered epitaxial stack; and a nitride layer comprising silicon nitride disposed on the pad oxide layer.

Clause 6. The workpiece and/or the method according to any one of Clauses 1-5, wherein the pad oxide layer has a thickness in a range from about 0.5 nm to about 5 nm, such as about 0.8 nm to about 4 nm, about 1 nm to about 3 nm, or about 1.5 nm to about 2.5 nm.

Clause 7. The workpiece and/or the method according to any one of Clauses 1-6, wherein the nitride layer has a thickness in a range from about 10 nm to about 50 nm, such as about 20 nm to about 40 nm, about 25 nm to about 35 nm, or about 28 nm to about 32 nm.

Clause 8. The workpiece and/or the method according to any one of Clauses 1-7, wherein each of the trenches extends into the substrate to a depth in a range from about 50 nm to about 250 nm.

Clause 9. The workpiece and/or the method according to any one of Clauses 1-8, wherein each of the trenches extends has a total depth of about 200, about 250 nm, about 300 nm, about 350 nm, about 400 nm, about 500 nm, or greater.

Clause 10. The workpiece and/or the method according to any one of Clauses 1-9, wherein the plurality of first silicon germanium layers and silicon channel layers of the bottom FET module comprises four of the first silicon germanium layers and three of the silicon channel layers alternately stacked on each other.

Clause 11. The workpiece and/or the method according to any one of Clauses 1-10, wherein the plurality of first silicon germanium layers and silicon channel layers of the top FET module comprises three of the first silicon germanium layers and three of the silicon channel layers alternately stacked on each other.

Clause 12. The workpiece and/or the method according to any one of Clauses 1-11, wherein the plurality of the first silicon germanium layers and second silicon germanium layers of the MDI film comprises three of the second silicon germanium layers and two of the first silicon germanium layers alternately stacked on each other.

Clause 13. The workpiece and/or the method according to any one of Clauses 1-12, wherein each of the first silicon germanium layers independently has a germanium concentration in a range from about 10 at % to about 20 at %, such as about 12 at % to about 18 at %, about 14 at % to about 16 at %, such as 15 at %.

Clause 14. The workpiece and/or the method according to any one of Clauses 1-13, wherein each of the first silicon germanium layers independently has a silicon concentration in a range from about 80 at % to about 90 at %, such as about 82 at % to about 88 at %, about 84 at % to about 86 at %, such as 85 at %.

Clause 15. The workpiece and/or the method according to any one of Clauses 1-14, wherein each of the first silicon germanium layers independently has a carbon concentration in a range from about 0.2 at % to about 1 at %, such as about 0.3 at % to about 0.8 at %, about 0.4 at % to about 0.6 at %, such as 0.5 at %.

Clause 16. The workpiece and/or the method according to any one of Clauses 1-15, wherein each of the first silicon germanium layers independently has a thickness in a range from about 5 nm to about 15 nm, such as about 6 nm to about 14 nm, about 8 nm to about 12 nm, or about 10 nm.

Clause 17. The workpiece and/or the method according to any one of Clauses 1-16, wherein each of the second silicon germanium layers independently has a germanium concentration in a range from about 30 at % to about 50 at %, such as about 32 at % to about 48 at %, about 34 at % to about 46 at %, or about 38 at % to about 42 at %, such as 40 at %.

Clause 18. The workpiece and/or the method according to any one of Clauses 1-17, wherein each of the second silicon germanium layers independently has a silicon concentration in a range from about 50 at % to about 70 at %, such as about 52 at % to about 68 at %, about 54 at % to about 66 at %, or about 58 at % to about 62 at %, such as 60 at %.

Clause 19. The workpiece and/or the method according to any one of Clauses 1-18, wherein each of the second silicon germanium layers independently has a carbon concentration in a range from about 0.2 at % to about 1 at %, such as about 0.3 at % to about 0.8 at %, about 0.4 at % to about 0.6 at %, such as 0.5 at %.

Clause 20. The workpiece and/or the method according to any one of Clauses 1-19, wherein each of the second silicon germanium layers independently has a thickness in a range from about 4 nm to about 12 nm, such as about 6 nm to about 10 nm, about 7 nm to about 9 nm, or about 8 nm.

Clause 21. The workpiece and/or the method according to any one of Clauses 1-20, wherein each of the silicon channel layers independently has a silicon concentration of greater than 95 at % to 100 at %, such as about 98 at % to 100 at %, about 99 at % to 100 at %, or about 99.5 at % to 100 at %.

Clause 22. The workpiece and/or the method according to any one of Clauses 1-21, wherein each of the silicon channel layers independently has a thickness in a range from about 5 nm to about 15 nm, such as about 6 nm to about 14 nm, about 8 nm to about 12 nm, or about 10 nm.

Clause 23. The workpiece and/or the method according to any one of Clauses 1-22, wherein each of the bottom silicon epi layers and the top silicon epi layers independently has a silicon concentration of greater than 95 at % to 100 at %, such as about 98 at % to 100 at %, about 99 at % to 100 at %, or about 99.5 at % to 100 at %.

Clause 24. The workpiece and/or the method according to any one of Clauses 1-23, wherein each of the bottom silicon epi layers and the top silicon epi layers independently has a thickness in a range from about 0.5 nm to about 4 nm, such as about 1 nm to about 3 nm, about 1.5 nm to about 2.5 nm, or about 2 nm.

Clause 25. The workpiece and/or the method according to any one of Clauses 1-24, wherein each of the bottom and top FET modules independently has a thickness in a range from about 40 nm to about 100 nm, such as about 50 nm to about 90 nm, about 55 nm to about 80 nm, or about 60 nm to about 70 nm.

Clause 26. The workpiece and/or the method according to any one of Clauses 1-25, wherein the bottom FET module has a thickness in a range from about 60 nm to about 80 nm, and the top FET module has a thickness in a range from about 50 nm to about 70 nm.

Clause 27. The workpiece and/or the method according to any one of Clauses 1-26, wherein the MDI film has a thickness in a range from about 35 nm to about 65 nm, such as about 40 nm to about 60 nm, about 45 nm to about 50 nm, or about 48 nm.

Clause 28. The workpiece and/or the method according to any one of Clauses 1-27, wherein the multi-layered epitaxial stack has a thickness in a range from about 130 nm to about 220 nm, such as about 150 nm to about 200 nm, or about 178 nm.

Clause 29. The workpiece and/or the method according to any one of Clauses 1-28, wherein the multi-layered epitaxial stack is a complementary field-effect transistor (cFET).

Clause 30. The workpiece and/or the method according to any one of Clauses 1-29, wherein each of the bottom FET module and the top FET module independently comprises a metal oxide semiconductor (MOS) film.

Clause 31. The workpiece and/or the method according to any one of Clauses 1-30, wherein the MDI film has a crystalline defect density of less than 158 pixels/cm², as measured by reflective X-ray diffraction imaging (XRDI).

Clause 32. The workpiece and/or the method according to any one of Clauses 1-31, wherein prior to the etching process, further comprising: depositing an oxide layer on the nitride layer; depositing an amorphous carbon layer on the oxide layer; depositing an anti-reflective coating (ARC) layer on the amorphous carbon layer; and depositing a photoresist layer on the ARC layer.

Clause 33. The workpiece and/or the method according to any one of Clauses 1-32, further comprising pattering and developing the photoresist layer to form a pattern of the features or the trenches during the etching process.

Clause 34. The workpiece and/or the method according to any one of Clauses 1-33, wherein the etching process comprises repeating a cyclic etch process to form the trenches, wherein the cyclic etch process comprises: exposing horizontal surfaces above the substrate to a main etch comprising an oxygen plasma; then depositing a passivation layer on horizontal and vertical surfaces above the substrate; then exposing the passivation layer on the horizontal surfaces to a fluoride reagent to selectively remove the passivation layer from the horizontal surfaces while maintaining the passivation layer on the vertical surfaces.

### Clause Group 3

Clause 1. A workpiece, comprising: a plurality of features separated by trenches and disposed on a substrate, wherein each of the trenches has an aspect ratio of greater than 10, and wherein each of the features comprises a multi-layered epitaxial stack comprising a middle dielectric isolation (MDI) film disposed between a bottom field effect transistor (FET) module and a top FET module, wherein: the bottom FET module is disposed on the substrate; the bottom FET module comprises a plurality of first silicon germanium layers and silicon channel layers, wherein the first silicon germanium layers and the silicon channel layers are alternately stacked on each other; the top FET module is disposed on the MDI film; the top FET module comprises a plurality of the first silicon germanium layers and the silicon channel layers, wherein the first silicon germanium layers and the silicon channel layers are alternately stacked on each other; and the MDI film comprises: a second silicon germanium layer containing a concentration of germanium greater than the first silicon germanium layers and greater than 25 at %; a bottom silicon epi layer disposed between the bottom FET module and the second silicon germanium layer; and a top silicon epi layer disposed between the top FET module and the second silicon germanium layer.

Clause 2. A workpiece, comprising: a plurality of features separated by trenches and disposed on a substrate, wherein each of the trenches has an aspect ratio of greater than 10, and wherein each of the features comprises a multi-layered epitaxial stack comprising a middle dielectric isolation (MDI) film disposed between a bottom field effect transistor (FET) module and a top FET module, wherein: the bottom FET module is disposed on the substrate; the bottom FET module comprises a plurality of first silicon germanium layers and silicon channel layers, wherein four of the first silicon germanium layers are alternately stacked with three of the silicon channel layers; the top FET module is disposed on the MDI film; the top FET module comprises a plurality of the first silicon germanium layers and the silicon channel layers, wherein three of the first silicon germanium layers are alternately stacked with three of the silicon channel layers; the MDI film comprises: a second silicon germanium layer containing a concentration of germanium greater than the first silicon germanium layers and greater than 25 at %; a bottom silicon epi layer disposed between the bottom FET module and the second silicon germanium layer; and a top silicon epi layer disposed between the top FET module and the second silicon germanium layer.

Clause 3. A method of fabricating a device, comprising: depositing a bottom field effect transistor (FET) module on a substrate; depositing a middle dielectric isolation (MDI) film on the bottom FET module; depositing a top FET module on the MDI film; wherein the bottom FET module comprises a plurality of first silicon germanium layers and silicon channel layers, wherein the first silicon germanium layers and the silicon channel layers are alternately stacked on each other; the top FET module comprises a plurality of the first silicon germanium layers and the silicon channel layers, wherein the first silicon germanium layers and the silicon channel layers are alternately stacked on each other; and the MDI film comprises: a second silicon germanium layer containing a concentration of germanium greater than the first silicon germanium layers and greater than 25 at %; a bottom silicon epi layer disposed between the bottom FET module and the second silicon germanium layer; and a top silicon epi layer disposed between the top FET module and the second silicon germanium layer; depositing a pad oxide layer comprising silicon oxide on the top FET module; depositing a nitride layer comprising silicon nitride on the pad oxide layer; and forming a plurality of features separated by trenches and disposed on the substrate by etching the trenches through at least the nitride layer, the pad oxide layer, the top FET module, the MDI film, and the bottom FET module during an etching process, wherein each of the trenches has an aspect ratio of greater than 10, and wherein each of the features comprises a multi-layered epitaxial stack comprising the MDI film disposed between the FET module and the top FET module, the pad oxide layer disposed on the top FET module, and the nitride layer disposed on the pad oxide layer.

Clause 4. The workpiece and/or the method according to any one of Clauses 1-3, wherein each of the trenches has an aspect ratio in a range from about 12 to about 20, such as about 14 to about 16.

Clause 5. The workpiece and/or the method according to any one of Clauses 1-4, wherein each of the features further comprises: a pad oxide layer comprising silicon oxide disposed on the multi-layered epitaxial stack; and a nitride layer comprising silicon nitride disposed on the pad oxide layer.

Clause 6. The workpiece and/or the method according to any one of Clauses 1-5, wherein the pad oxide layer has a thickness in a range from about 0.5 nm to about 5 nm, such as about 0.8 nm to about 4 nm, about 1 nm to about 3 nm, or about 1.5 nm to about 2.5 nm.

Clause 7. The workpiece and/or the method according to any one of Clauses 1-6, wherein the nitride layer has a thickness in a range from about 10 nm to about 50 nm, such as about 20 nm to about 40 nm, about 25 nm to about 35 nm, or about 28 nm to about 32 nm.

Clause 8. The workpiece and/or the method according to any one of Clauses 1-7, wherein each of the trenches extends into the substrate to a depth in a range from about 50 nm to about 250 nm, and/or wherein each of the trenches extends has a total depth of about 200, about 250 nm, about 300 nm, about 350 nm, about 400 nm, about 500 nm, or greater.

Clause 9. The workpiece and/or the method according to any one of Clauses 1-9, wherein the plurality of first silicon germanium layers and silicon channel layers of the bottom FET module comprises four of the first silicon germanium layers and three of the silicon channel layers alternately stacked on each other.

Clause 10. The workpiece and/or the method according to any one of Clauses 1-9, wherein the plurality of first silicon germanium layers and silicon channel layers of the top FET module comprises three of the first silicon germanium layers and three of the silicon channel layers alternately stacked on each other.

Clause 11. The workpiece and/or the method according to any one of Clauses 1-10, wherein each of the first silicon germanium layers independently has a germanium concentration in a range from about 10 at % to about 20 at %, such as about 12 at % to about 18 at %, or about 14 at % to about 16 at %, such as 15 at %.

Clause 12. The workpiece and/or the method according to any one of Clauses 1-11, wherein each of the first silicon germanium layers independently has a silicon concentration in a range from about 80 at % to about 90 at %, such as about 82 at % to about 88 at %, or about 84 at % to about 86 at %, such as 85 at %.

Clause 13. The workpiece and/or the method according to any one of Clauses 1-12, wherein each of the first silicon germanium layers independently has a carbon concentration in a range from about 0.2 at % to about 1 at %, such as about 0.3 at % to about 0.8 at %, or about 0.4 at % to about 0.6 at %, such as 0.5 at %.

Clause 14. The workpiece and/or the method according to any one of Clauses 1-13, wherein each of the first silicon germanium layers independently has a thickness in a range from about 5 nm to about 15 nm, such as about 6 nm to about 14 nm, about 8 nm to about 12 nm, or about 10 nm.

Clause 15. The workpiece and/or the method according to any one of Clauses 1-14, wherein the second silicon germanium layer has a germanium concentration in a range from about 30 at % to about 50 at %, such as about 32 at % to about 48 at %, about 34 at % to about 46 at %, or about 38 at % to about 42 at %, such as 40 at %.

Clause 16. The workpiece and/or the method according to any one of Clauses 1-15, wherein the second silicon germanium layer has a silicon concentration in a range from about 50 at % to about 70 at %, such as about 52 at % to about 68 at %, about 54 at % to about 66 at %, or about 58 at % to about 62 at %, such as 60 at %.

Clause 17. The workpiece and/or the method according to any one of Clauses 1-16, wherein the second silicon germanium layer has a carbon concentration in a range from about 0.2 at % to about 1 at %, such as about 0.3 at % to about 0.8 at %, or about 0.4 at % to about 0.6 at %, such as 0.5 at %.

Clause 18. The workpiece and/or the method according to any one of Clauses 1-17, wherein the second silicon germanium layer has a thickness in a range from about 40 nm to about 80 nm, such as about 45 nm to about 70 nm, about 40 nm to about 50 nm, about 50 nm to about 70 nm, or about 55 nm to about 65 nm, for examples, about 45 nm or about 60 nm.

Clause 19. The workpiece and/or the method according to any one of Clauses 1-18, wherein each of the silicon channel layers independently has a silicon concentration of greater than 95 at % to 100 at %, such as about 98 at % to 100 at %, about 99 at % to 100 at %, or about 99.5 at % to 100 at %.

Clause 20. The workpiece and/or the method according to any one of Clauses 1-19, wherein each of the silicon channel layers independently has a thickness in a range from about 5 nm to about 15 nm, such as about 6 nm to about 14 nm, or about 8 nm to about 12 nm, or about 10 nm.

Clause 21. The workpiece and/or the method according to any one of Clauses 1-20, wherein each of the bottom silicon epi layers and the top silicon epi layers independently has a silicon concentration of greater than 95 at % to 100 at %, such as about 98 at % to 100 at %, about 99 at % to 100 at %, or about 99.5 at % to 100 at %.

Clause 22. The workpiece and/or the method according to any one of Clauses 1-21, wherein each of the bottom silicon epi layers and the top silicon epi layers independently has a thickness in a range from about 0.5 nm to about 4 nm, such as about 1 nm to about 3 nm, about 1.5 nm to about 2.5 nm, or about 2 nm.

Clause 23. The workpiece and/or the method according to any one of Clauses 1-22, wherein each of the bottom and top FET modules independently has a thickness in a range from about 40 nm to about 100 nm, such as about 50 nm to about 90 nm, about 55 nm to about 80 nm, or about 60 nm to about 70 nm.

Clause 24. The workpiece and/or the method according to any one of Clauses 1-23, wherein the bottom FET module has a thickness in a range from about 60 nm to about 80 nm, and the top FET module has a thickness in a range from about 50 nm to about 70 nm.

Clause 25. The workpiece and/or the method according to any one of Clauses 1-24, wherein the MDI film has a thickness in a range from about 35 nm to about 65 nm, such as about 40 nm to about 55 nm, about 45 nm to about 50 nm, or about 48 nm.

Clause 26. The workpiece and/or the method according to any one of Clauses 1-25, wherein the multi-layered epitaxial stack has a thickness in a range from about 130 nm to about 220 nm, such as about 150 nm to about 200 nm, or about 178 nm.

Clause 27. The workpiece and/or the method according to any one of Clauses 1-26, wherein the multi-layered epitaxial stack is a complementary field-effect transistor (cFET).

Clause 28. The workpiece and/or the method according to any one of Clauses 1-27, wherein each of the bottom FET module and the top FET module independently comprises a metal oxide semiconductor (MOS) film.

Clause 29. The workpiece and/or the method according to any one of Clauses 1-28, wherein the MDI film has a crystalline defect density of less than 158 pixels/cm², as measured by reflective X-ray diffraction imaging (XRDI).

Clause 30. The workpiece and/or the method according to any one of Clauses 1-29, wherein prior to the etching process, further comprising: depositing an oxide layer on the nitride layer; depositing an amorphous carbon layer on the oxide layer; depositing an anti-reflective coating (ARC) layer on the amorphous carbon layer; and depositing a photoresist layer on the ARC layer.

Clause 31. The workpiece and/or the method according to any one of Clauses 1-30, further comprising pattering and developing the photoresist layer to form a pattern of the features or the trenches during the etching process.

Clause 32. The workpiece and/or the method according to any one of Clauses 1-31, wherein the etching process comprises repeating a cyclic etch process to form the trenches, wherein the cyclic etch process comprises: exposing horizontal surfaces above the substrate to a main etch comprising an oxygen plasma; then depositing a passivation layer on horizontal and vertical surfaces above the substrate; then exposing the passivation layer on the horizontal surfaces to a fluoride reagent to selectively remove the passivation layer from the horizontal surfaces while maintaining the passivation layer on the vertical surfaces.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications may be made without departing from the spirit and scope of the present disclosure. Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation may be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

What is claimed is:

1. A workpiece, comprising:
a multi-layered epitaxial stack disposed on a substrate, wherein the multi-layered epitaxial stack comprises a middle dielectric isolation (MDI) film disposed between a bottom field effect transistor (FET) module and a top FET module, wherein:
the bottom FET module is disposed on the substrate;
the bottom FET module comprises a plurality of first silicon germanium layers and silicon channel layers, wherein the first silicon germanium layers and the silicon channel layers are alternately stacked on each other;
the top FET module is disposed on the MDI film;
the top FET module comprises a plurality of the first silicon germanium layers and the silicon channel layers, wherein the first silicon germanium layers and the silicon channel layers are alternately stacked on each other; and
the MDI film comprises:
a plurality of the first silicon germanium layers and second silicon germanium layers, wherein the first silicon germanium layers the second silicon germanium layers are alternately stacked on each other, and wherein the second silicon germanium layers have a greater germanium concentration than the first silicon germanium layers;
a bottom silicon epi layer disposed between the bottom FET module and the plurality of the first silicon germanium layers and the second silicon germanium layers; and
a top silicon epi layer disposed between the top FET module and the plurality of the first silicon germanium layers and the second silicon germanium layers.

2. The workpiece of claim 1, wherein the plurality of first silicon germanium layers and silicon channel layers of the bottom FET module comprises three of the first silicon germanium layers and two of the silicon channel layers alternately stacked on each other.

3. The workpiece of claim 1, wherein the plurality of first silicon germanium layers and silicon channel layers of the top FET module comprises two of the first silicon germanium layers and two of the silicon channel layers alternately stacked on each other.

4. The workpiece of claim 1, wherein the plurality of the first silicon germanium layers and second silicon germanium layers of the MDI film comprises three of the second silicon germanium layers and two of the first silicon germanium layers alternately stacked on each other.

5. The workpiece of claim 1, wherein each of the first silicon germanium layers independently has a germanium concentration in a range from about 10 at % to about 20 at % and a carbon concentration in a range from about 0.2 at % to about 1 at %.

6. The workpiece of claim 1, wherein each of the first silicon germanium layers independently has a silicon concentration in a range from about 80 at % to about 90 at %.

7. The workpiece of claim 1, wherein each of the first silicon germanium layers independently has a thickness in a range from about 5 nm to about 15 nm.

8. The workpiece of claim 1, wherein each of the second silicon germanium layers independently has a germanium concentration in a range from about 30 at % to about 50 at % and a carbon concentration in a range from about 0.2 at % to about 1 at %.

9. The workpiece of claim 1, wherein each of the second silicon germanium layers independently has a silicon concentration in a range from about 50 at % to about 70 at %.

10. The workpiece of claim 1, wherein each of the second silicon germanium layers independently has a thickness in a range from about 4 nm to about 12 nm.

11. The workpiece of claim 1, wherein each of the silicon channel layers independently has a silicon concentration of greater than 95 at % to 100 at %, and wherein each of the silicon channel layers independently has a thickness in a range from about 5 nm to about 15 nm.

12. The workpiece of claim 1, wherein each of the bottom silicon epi layers and the top silicon epi layers independently has a silicon concentration of greater than 95 at % to 100 at %, and wherein each of the bottom silicon epi layers and the top silicon epi layers independently has a thickness in a range from about 0.5 nm to about 4 nm.

13. The workpiece of claim 1, wherein the bottom FET module has a thickness in a range from about 40 nm to about 60 nm, the top FET module has a thickness in a range from about 30 nm to about 50 nm, and the MDI film has a thickness in a range from about 35 nm to about 65 nm.

14. The workpiece of claim 1, wherein the multi-layered epitaxial stack has a wafer bow in a range from about 40 μm to about 70 μm.

15. The workpiece of claim 1, wherein a top interface of the bottom FET module comprises the first silicon germanium layer having an abruptness value in a range from about 1.1 nm to about 1.4 nm, and wherein a bottom interface of the bottom FET module comprises the first silicon germanium layer having an abruptness value in a range from about 1.0 nm to about 1.3 nm.

16. The workpiece of claim 1, wherein a bottom interface of the top FET module comprises the first silicon germanium layer having an abruptness value in a range from about 1.0 nm to about 1.3 nm, and wherein a top interface of the top FET module comprises the silicon channel layer having an abruptness value in a range from about 1.0 nm to about 1.3 nm.

17. A workpiece, comprising:
a multi-layered epitaxial stack disposed on a substrate, wherein the multi-layered epitaxial stack comprises a middle dielectric isolation (MDI) film disposed between a bottom field effect transistor (FET) module and a top FET module, wherein:
the bottom FET module is disposed on the substrate;
the bottom FET module comprises a plurality of first silicon germanium layers and silicon channel layers, wherein three of the first silicon germanium layers are alternately stacked with two of the silicon channel layers;
the top FET module is disposed on the MDI film;
the top FET module comprises a plurality of the first silicon germanium layers and the silicon channel layers, wherein two of the first silicon germanium layers are alternately stacked with two of the silicon channel layers;
the MDI film comprises a plurality of the first silicon germanium layers and second silicon germanium layers, wherein three of the second silicon germanium layers are alternately stacked with two of the first silicon germanium layers, and wherein the second silicon germanium layers have a greater germanium concentration than the first silicon germanium layers; and
the MDI film further comprises a bottom silicon epi layer disposed between the bottom FET module and the plurality of the first silicon germanium layers and the second silicon germanium layers and a top silicon epi layer disposed between the top FET module and the plurality of the first silicon germanium layers and the second silicon germanium layers.

18. A method of fabricating a film stack, comprising:
depositing a bottom field effect transistor (FET) module on a substrate at a first temperature in a range from about 575° C. to about 625° C.;
depositing a middle dielectric isolation (MDI) film on the bottom FET module at a second temperature in a range from about 575° C. to about 625° C.; and
depositing a top FET module on the MDI film at a third temperature in a range from about 575° C. to about 625° C.; wherein
the bottom FET module comprises a plurality of first silicon germanium layers and silicon channel layers, wherein the first silicon germanium layers and the silicon channel layers are alternately stacked on each other;
the top FET module comprises a plurality of the first silicon germanium layers and the silicon channel layers, wherein the first silicon germanium layers and the silicon channel layers are alternately stacked on each other; and
the MDI film comprises:
a plurality of the first silicon germanium layers and second silicon germanium layers, wherein the first silicon germanium layers the second silicon germanium layers are alternately stacked on each other, and wherein the second silicon germanium layers have a greater germanium concentration than the first silicon germanium layers;
a bottom silicon epi layer disposed between the bottom FET module and the plurality of the first silicon germanium layers and the second silicon germanium layers; and
a top silicon epi layer disposed between the top FET module and the plurality of the first silicon germanium layers and the second silicon germanium layers.

19. The method of claim 18, wherein each of the first, second, and third temperatures is independently in a range from about 590° C. to about 610° C., and wherein each of the first silicon germanium layers and each the second silicon germanium layers independently contain carbon.

20. The method of claim 18, wherein each of the first silicon germanium layers and each the second silicon germanium layers are independently deposited from a deposition gas by an epitaxial process, and wherein the deposition gas comprises hydrogen (H₂), a silicon precursor, a silicon chlorine precursor, a silicon carbon precursor, and a germanium precursor.
